(19) United States
(12) Patent Application Publication
(10) Pub. No.: US 2014/0083859 A1
(43) Pub. Date: Mar. 27, 2014

(54) BIOFUNCTIONAL NANOFIBERS FOR ANALYTE SEPARATION IN MICROCHANNELS

(71) Applicants: Antje J. Baeumner, Ithaca, NY (US); Margaret W. Frey, Ithaca, NY (US); Daehwan Cho, Austin, TX (US)

(72) Inventors: Antje J. Baeumner, Ithaca, NY (US); Margaret W. Frey, Ithaca, NY (US); Daehwan Cho, Austin, TX (US)

(73) Assignee: Cornell University, Ithaca, NY (US)

(21) Appl. No.: 14/007,040

(22) PCT Filed: Mar. 23, 2012
(86) PCT No.: PCT/US2012/030429

§ 371 Date: Dec. 3, 2013

Related U.S. Application Data
(60) Provisional application No. 61/467,197, filed on Mar. 24, 2011.

(51) Int. Cl. B81B 1/00; B81C 1/00

(52) U.S. Cl. CPC B81B 1/006; B81C 1/00119
USPC 204/601; 156/244.17

(57) ABSTRACT

A method is provided for producing, in a substrate, an enclosed channel or enclosed cavity comprising at least one functional nanofiber, the method comprising the steps of providing a first substrate and a second substrate; forming a channel or cavity on the first substrate or the second substrate; electrospinning at least one functional nanofiber on the first substrate; assembling the first and second substrates, wherein the first substrate is placed over the second substrate, or the second substrate is placed over the first substrate; and bonding the first substrate and the second substrate to form the substrate, thereby forming an enclosed channel or enclosed cavity comprising the at least one functional nanofiber in the substrate. An enclosed channel or cavity comprising at least one functional electrospun nanofiber is also provided. A microfluidic device is also provided comprising an enclosed channel or cavity comprising at least one functional electrospun nanofiber.

### CROSS-REFERENCE TO RELATED APPLICATIONS

This application claims priority to and the benefit of co-pending U.S. provisional patent application Ser. No. 61/467,197, entitled Biofunctional Nanofibers for Analyte Separation in Microfluidic Channels, filed Mar. 24, 2011, which is incorporated herein by reference in its entirety.

### STATEMENT REGARDING FEDERALLY SPONSORED RESEARCH OR DEVELOPMENT

The disclosed invention was made with government support under grant no. 0852900 from the Division of Chemical, Bioengineering, Environmental, and Transport Systems of the National Science Foundation. The government has rights in this invention.

### 1. TECHNICAL FIELD

The present invention relates to methods for producing microscale channels or cavities comprising functional nanofibers. The invention further relates to microfluidic devices and other microscale devices comprising microscale channels or cavities that comprise functional nanofibers. The invention also relates to microfluidic devices and other microscale devices into which functional nanofibers have been integrated.

### 2. BACKGROUND OF THE INVENTION

As microfluidic devices have advanced in sophistication the range of applications has also expanded rapidly. Initially all devices were made in silicon. Advances into production on glass and, more recently, polymeric materials such as polydimethyl siloxane (PDMS), polymethyl methacrylate (PMMA), polystyrene (PS) and other polymers has increased the range of uses and the ease of fabrication while decreasing the material costs. This transition has been accompanied by advancement in fabrication technologies including soft-lithography and nano-imprinting for rapid prototyping. Driving forces for these developments have been the need for materials that are biocompatible, translucent and flexible with a greater variety of surface chemistries and for more economical, less clean-room intensive processing. Simultaneously, the applications for microfluidic devices have expanded from single function chips to complex micro total analysis systems (microTAS) and effective microfluidic in vitro models. Several research teams have realized that the limitations of microfluidic devices could be ameliorated by incorporating nanofibers within channels. Methods for making aligned fibers or arranging fibers patches with specific size and shape by selectively etching fibers on glass substrates have been described (Yang, H.; Dong, L., Selective Nanofiber Deposition Using a Microfluidic Confinement Approach. Langmuir 2009, 26 (3), 1539-1543). A detailed study of nanofiber behavior during low Reynold's number flows in microfluidic channels confirmed that fibers do not fold or buckle within the channels under these conditions (Sadlej, K.; Wajnryb, E.; Ekiel-Jeżewska, M. L.; Lamparska, D.; Kowalewski, T. A., Dynamics of nanofibres conveyed by low Reynolds number flow in a microchannel. International Journal of Heat & Fluid Flow 2010, 31 (6), 996-1004). Nanofibers are stable within channels at high flow rates.

Applications for nanofibers within microfluidic devices to-date have taken advantage of nanofiber arrays as scaffolds for cell growth within microfluidic in vitro model devices and the selective filtration capabilities of nanofibers. Lee et al. incorporated a patch of randomly oriented polyurethane nanofibers into a microfluidic channel. The nanofibers were used as a synthetic extracellular matrix (ECM) for growth of human Mesenchymal Stem Cell (hMSC) within the channel of a bio-MEMS device. With this microfluidic construct: hMSC were grown on a synthetic ECM within a channel, various nutrients could be provided via flow through the channel (Lee, K. H.; Kwon, G. H.; Shin, S. J.; Baek, J.-Y.; Han, D. K.; Park, Y.; Lee, S. H., Hydrophilic electrospun polyurethane nanofiber matrices for hMSC culture in a microfluidic cell chip. Journal Of Biomedical Materials Research. Part A 2009, 90 (2), 619-628). Lee et al. (Lee, K. H.; Kim, D. J.; Min, B. G.; Lee, S. H., Polymeric nanofiber web-based artificial renal microfluidic chip. Biomedical Microdevices 2007, 9 (4), 435-442) created a microfluidic dialysis device by a) electrospinning a non-woven filter fabric, b) making a PDMS microfluidic device, top and bottom containing a serpentine etched channel and c) sandwiching the electrospun fabric between the top and bottom of the microfluidic device. As a prototype device, the preliminary dialysis results were as good as or better than currently available systems.

Advantages of microfluidic devices over bench-top procedures include lower reagent volumes, increased surface/volume ratios, and the ease of physical and chemical microenvironment control for biological systems. Diffusion limited transport is a draw-back for many microfluidic devices, in particular those that require fast mixing or high chemical reaction rate at the interfaces of the fluid flow and the channel walls.

Limitations in the capabilities of the current materials and structures, however, now motivate invention of new materials, features and processing methods.

Citation or identification of any reference in Section 2, or in any other section of this application, shall not be considered an admission that such reference is available as prior art to the present invention.

### 3. SUMMARY OF THE INVENTION

A method is provided for producing, in a substrate, an enclosed channel or enclosed cavity comprising at least one functional nanofiber, the method comprising the steps of:

providing a first substrate and a second substrate;

forming a channel (or groove) or cavity on either the first substrate or the second substrate or on both the first substrate and the second substrate;

electrospinning at least one functional nanofiber on the first substrate;

assembling the first and second substrates, wherein:
the first substrate is placed over the second substrate, or
the second substrate is placed over the first substrate; and

bonding the first substrate and the second substrate to form the substrate, thereby forming an enclosed channel or enclosed cavity comprising the at least one functional nanofiber in the substrate.

In specific embodiments, the steps of the method can vary in order.

In other embodiments, the first or second substrates can be, e.g., flat, flexible, rough, smooth or patterned.

In another embodiment, the enclosed channel or enclosed cavity can comprise at least one inlet and/or at least one outlet.

In another embodiment, the first substrate or the second substrate can comprise Poly(methyl methacrylate) (PMMA), polycarbonate (PC), polystyrene (PS), Polydimethylsiloxane (PDMS), polyethylene (PE), cyclic olefin copolymer (COC) or other suitable polymers known in the art, or agarose, glass, metals, silicon or other suitable substrates known in the art.

In another embodiment, the step of electrospinning the at least one functional nanofiber produces the at least one functional nanofiber in a desired orientation.

In specific embodiments, at least one nanofiber can be positioned or oriented within the enclosed channel or enclosed cavity in a desired orientation that is a direction substantially parallel to, or across the width or transverse diameter of the enclosed channel or enclosed cavity (e.g., parallel to an axis substantially perpendicular to the long(est) axis or length of the channel or cavity).

In other embodiments, the nanofiber(s) can be positioned or oriented in a desired orientation that is substantially parallel to, or along the long(est) axis or length of the enclosed channel or enclosed cavity.

In other embodiments, the nanofiber(s) can be positioned or oriented in a desired orientation that is a random orientation across the length or across the width of the enclosed channel or enclosed cavity.

In other embodiments, the nanofiber(s) can be positioned or oriented in a desired orientation that is a random distribution within the enclosed channel or enclosed cavity).

In other embodiments, the nanofiber(s) can be positioned or oriented in a tuft or mat positioned in the interior (or comprised in) the enclosed channel or enclosed cavity.

In a specific embodiment, a plurality of functional nanofibers is electrospun. In various embodiments, the plurality of electrospun functional nanofibers can be meshed together or physically contacting one another, or preferably, separated in different locations in the interior of the enclosed channel or enclosed cavity, with the positions or orientations as described above.

In another embodiment, nanofibers can be positioned so that at a given location, the nanofibers are parallel to a particular axis or landmark in the channel or cavity and at another location, are perpendicular, diagonal, or in another orientation.

In another embodiment, at least one functional nanofiber on the first substrate is positioned partially or in its entirety in a channel or cavity in the first substrate.

In another embodiment, at least one functional nanofiber on the first substrate is positioned partially or in its entirety in functional contact with a channel or cavity in the second substrate upon bonding (or placing) the two substrates together.

In another embodiment, the method can additionally comprise, between the step of forming a channel or cavity and the step of electrospinning, the step of depositing at least one conductive surface on a surface of the first substrate or on a surface of the second substrate.

In specific embodiments, the conductive surface is deposited on an interior surface of the first substrate or the second substrate (i.e., the surface that will subsequently be facing towards the interior or inside the channel) or an exterior surface of the first substrate or the second substrate (i.e., the surface that will subsequently be on the exterior or on the outside of the channel).

In another embodiment, the conductive surface can be glued or otherwise affixed, according to methods known in the art, to a surface of a substrate prior to the electrospinning step. Alternatively, the conductive surface can be microfabricated on the surface of the substrate prior to the electrospinning step. Electrospinning can then be conducted after the substrate has been put into contact with the conductive surface.

In some embodiments, the conductive surface can be part of the electrospinning apparatus. Also in this embodiment, however, the substrate will first be located in proximity of this conductive surface and subsequently the nanofibers will be spun onto the surface.

In one embodiment, the conductive surface is positioned (or deposited) on the first substrate and the nanofibers are spun onto that substrate rather than the second substrate. In another embodiment, the conductive surface is positioned (or deposited) on the second substrate and the nanofibers are spun onto that substrate rather than the first substrate.

In another embodiment, at least one conductive surface is an electrode.

In another embodiment, the nanofiber contacts or is connected to at least one of the conductive surface(s).

In another embodiment, the nanofiber does not contact or is not connected to a conductive surface.

In a specific embodiment, at least one conductive surface is adjacent to the channel or cavity.

In another embodiment, at least a first conductive surface and a second conductive surface are deposited. The first conductive surface and the second conductive surface can be positioned on substantially opposite interior sides, substantially opposite exterior sides, or on an interior side substantially opposite an exterior side, of the enclosed channel or enclosed cavity.

In a specific embodiment, a plurality of conductive surfaces is deposited.

In another embodiment, the members of a plurality of conductive surfaces are all physically or functionally connected to each other, i.e., they are not separate.

However, in other embodiments, at least one of the conductive surfaces is separate, i.e., does not physically or functionally connect to another conductive surface.

In another embodiment, the bonding step is irreversible or reversible or wherein the enclosed channel or enclosed cavity is irreversibly or reversibly bonded.

In another embodiment, the nanofiber is conductive.

In another embodiment, the nanofiber comprises a biorecognition element.

In another embodiment, the nanofiber comprises a chemical functionality on a surface of the nanofiber, i.e., the nanofiber can have a chemical functionality located on its surface.

In another embodiment, the nanofiber comprises positive charges and/or negative charges on the surface of the nanofiber, i.e., the nanofiber can have positive and/or negative charges located on its surface.

In another embodiment, the nanofiber comprises a functional group that can be protonated or deprotonated on a surface of the nanofiber, i.e., the nanofiber can have a functional group located on its surface.

In another embodiment, the functional group is selected from the group consisting of amine, nitrate, carboxyl, hydroxyl, peroxide, sulfhydryl, maleimide, reactive group and protected reactive group.

In another embodiment, the diameter of the nanofiber is 1-1000 nm

In another embodiment, the nanofiber comprises a first (main) polymer or a plurality of main polymers.

In another embodiment, the nanofiber additionally comprises at least one second (additive) polymer.

In another embodiment, the first or main polymer is selected from the group consisting of polyvinyl alcohol (PVA), Poly(lactic acid) (PLA), cellulose nitrate, cellulose acetate, polyamide, polyethylene oxide (PEO), polyacrylonitrile (PAN), collagen or other extracellular matrix (ECM) components known in the art.

In another embodiment, the at least one second (additive) polymer is selected from the group consisting of Hexadimethrine bromide (Polybrene), Poly(methyl vinyl ether-alt-maleic anhydride) (Poly(MVE/MA), Poly(3,4-ethylenedioxythiophene) poly(styrenesulfonate) (PEDOT:PSS), DNA, RNA, PNA, peptides, oligosaccharides and naturally occurring polymers.

In another embodiment, the nanofiber is a PVA/Polybrene or a PVA/Poly(MVE/MA) nanofiber.

A microfluidic device is also provided comprising a bonded channel or cavity comprising at least one functional electrospun nanofiber.

In one embodiment, the microfluidic device comprises:

a substrate, wherein the substrate comprises a first substrate and a second substrate bonded together; and

an enclosed channel or enclosed cavity, wherein the enclosed channel or enclosed cavity comprises:
a portion of the first substrate and a portion of the second substrate bonded together, and
at least one functional electrospun nanofiber positioned in the enclosed channel or enclosed cavity.

In a preferred embodiment, the enclosed channel or enclosed cavity comprises an inlet and/or an outlet.

A microfluidic device comprising:

a substrate, wherein the substrate comprises a first substrate and a second substrate bonded together; and

an enclosed channel or enclosed cavity, wherein the enclosed channel or enclosed cavity comprises:
a portion of the first substrate and a portion of the second substrate bonded together, and
at least one functional electrospun nanofiber positioned in the enclosed channel or enclosed cavity.

In a preferred embodiment, the enclosed channel or enclosed cavity comprises an inlet and/or an outlet.

In another embodiment, the enclosed channel or enclosed cavity comprises a channel (or groove) or cavity formed in the first substrate and/or the second substrate prior to the bonding of the first substrate and the second substrate.

In another embodiment, at least one functional nanofiber is positioned within the enclosed channel or enclosed cavity in:
(a) an orientation or direction that is substantially parallel to, or across the width or transverse diameter of the enclosed channel or enclosed cavity or that is substantially parallel to, or along the long (or longest) axis or length of the enclosed channel or enclosed cavity,
(b) a random orientation across the length or across the width of the enclosed channel or enclosed cavity,
(c) a random distribution within the enclosed channel or enclosed cavity, or
(d) a tuft or mat positioned in the interior (or comprised in) the enclosed channel or enclosed cavity.

In another embodiment, the device additionally comprises at least one conductive surface. In a preferred embodiment, the conductive surface is on a surface of the substrate.

In another embodiment, a step of purifying, isolating, concentrating and/or detecting a sample or analyte of interest is conducted in the enclosed channel or enclosed cavity.

An enclosed channel or enclosed cavity, wherein the enclosed channel or enclosed cavity comprises:

a portion of a first substrate and a portion of a second substrate bonded together, and

at least one functional electrospun nanofiber positioned in the enclosed channel or enclosed cavity.

### 4. BRIEF DESCRIPTION OF THE DRAWINGS

The present invention is described herein with reference to the accompanying drawings, in which similar reference characters denote similar elements throughout the several views. It is to be understood that in some instances, various aspects of the invention may be shown exaggerated or enlarged to facilitate an understanding of the invention.

FIGS. 1A-B. Illustration of collisions (stars) of analyte or particles (circles) with functionalized surfaces in A: a conventional microfluidic channel with pillars on the bottom; in B: nanofibers within the bulk of the channel. The top view shows the collisions of particles with the functionalized surfaces in a given cross section at a given time point.

FIGS. 2A-B. A. As the test fluid flows from left to right in the microfluidic channel, analyte and impurities are selectively captured. B. A buffer solution transports the purified analyte to specific capture probes for detection.

FIG. 3. Schematic diagram of steps for producing charged electrospun fibers.

FIGS. 4A-B. Polymethyl methacrylate (PMMA) electrode chip showing (A) a variety of sizes in electrode gaps and squares (A), and (B) a long gap between two electrodes.

FIGS. 5A-B. Schematic microfluidic device showing (A) the forming of a microfluidic channel with fibers aligned across the channel, and (B) a top view of a channel incorporated with fibers.

FIGS. 6A-C. Scanning electron microscope (SEM) images of electrospun fibers on aluminum foil: (A) pure PVA nanofibers, (B) Polybrene incorporated PVA nanofibers, and (C) Poly(MVE/MA) incorporated PVA nanofibers.

FIGS. 7A-B. FTIR spectra of (A) pure PVA electrospun nanofibers (a), PVA/Polybrene hybrid nanofibers (b), and PVA/Poly(MVE/MA) hybrid nanofibers (c) and (B) magnified FTIR spectra (1200-900 cm⁻¹).

FIG. 8. XPS spectra of pure PVA electrospun nanofibers (a), PVA/Polybrene hybrid nanofibers (b), and PVA/Poly(MVE/MA) hybrid nanofibers (c).

FIGS. 9A-D. Scanning electron micrographic (SEM) (A-C) and photographed (D) images of electrospun nanofibers on gold electrodes; accumulated nanofibers on an electrode (A) and aligned electrospun fibers across the electrodes (B-D).

FIGS. 10A-B. Light microscope images of aligned nanofibers along the gold electrodes: image captured by a magnification lens of (A) 10×, and (B) 1.5×.

FIGS. 11A-B. Light microscopy images of nanofibers aligned across channels in assembled microfluidic at low (A) and high (B) fiber density

FIG. 12. FTIR spectra of three simulated solutions, two effluents, and deionized (DI) water.

FIG. 13. ¹H NMR spectra of the calibration solutions and two effluents.

FIGS. 14A-D. Microscope images of aligned nanofibers along gold electrodes (A) 10× and (B) 1.5× magnified. Images (C) and (D) show nanofibers spun randomly at two different densities.

FIG. 15. Bacterial cells (E. coli) stained with a dye and captured on nanofibers in a microchannel.

FIGS. 16A-C. Laboratory scale electrospinning apparatus (left) has a high voltage supply, one or more syringes to feed polymer solution and a grounded collector. The grounding pattern on the collector can be arranged to collect fibers for assembly into microfluidic devices (right): A. perpendicular, B. parallel, or C. randomly within channels.

FIG. 17. (Left) Surface modification of PMMA via UV treatment and cystamine chemistry resulting in an adhering layer for gold electrodes realized as interdigitated electrode arrays for previous detection applications (right panels, a-b).

FIG. 18 (Top) Isolation of negatively charged nanovesicles using positively charged nanofibers (Polybrene/PVA polymer). Nanovesicles are synthesized, entrapping fluorescence molecules detectable using a fluorescence microscope. (Bottom) No nanovesicles were isolated using negatively charged nanofibers (Poly(methyl vinyl ether-alt-maleic anhydride)/PVA).

FIG. 19. Isolation and quantification of E. coli cells collected on positively charged fibers. Cells leaving the microchannel were quantified via plate count (top). Only positively charged fibers retained any cells within the channels (bottom left). Cells were stained using syto9 stain and visualized with a fluorescence microscope when bound to the fibers (bottom right).

FIG. 20. Five-fingered gold electrode design fabricated on PMMA.

FIG. 21. Completed microfluidic device comprising four channels containing functionalized nanofiber mats.

FIG. 22. (Top) Microchannel containing positive nanofibers full of liposomes (left) and after HSS wash (right). (Bottom) Microchannel containing negative nanofibers full of liposomes (left) and after HSS wash (right). Images were taken using 200× magnification. Single liposomes cannot be resolved at this magnification and high liposome concentration. Overall fluorescence is observed as generated by the liposome encapsulant solution.

FIG. 23. Comparison of liposome retention in positively (open symbols) and negatively (solid symbols) charged nanofiber mats within the microchannels. Liposomes were flown through the device for 30 minutes and then washed out using HSS buffer. Shown here is the step in which wash buffer enters the microfluidic channel. The initial high values are due to the pure liposome solution contained within the channels at the beginning of the wash step. Images were taken every 5 minutes and analyzed for red pixel intensity using Adobe® Photoshop®. Each line represents the average behavior of five different microchannels. The standard deviation represents variation between each of the microchannels.

FIG. 24. Confocal images showing the (left) top and (right) side of a positive nanofiber mat containing CDots (International Patent Application Publication No. WO 2004/063387 A2, Cornell University, Ithaca, N.Y.). CDots contain TRITC and enable fluorescence detection (emission 572 nm, excitation 541 nm)

FIG. 25. Comparison of fiber mat fluorescence (left) before and (right) after liposome flow and HSS wash.

FIG. 26. Zeta potential of polybrene incorporated PVA hybrid fibers as a function of pH.

FIGS. 27A-C. Exemplary curve for liposome retention within Polybrene-modified PVA nanofibers (thickness 25 μm) during pH 9 wash. (A) Fluorescence image of channel full of liposomes (B) Fluorescence image of channel during pH 7 wash (C) Fluorescence image of channel during pH 9 wash.

FIG. 28. Bar graph of exemplary data for the successful reuse of positively charged nanofibers to capture and release negatively charged liposomes. First bar, channel full of liposomes. Second bar, pH9 wash. Third bar, channel full of liposomes. Fourth bar, pH7 wash. Fifth bar, pH9 wash.

### 5. DETAILED DESCRIPTION OF THE INVENTION

A method for producing, in a substrate, an enclosed channel or enclosed cavity comprising at least one functional nanofiber, the method comprising the steps of:

providing a first substrate and a second substrate;
forming a channel or cavity on either the first substrate or the second substrate or on both the first substrate and the second substrate;
electrospinning at least one functional nanofiber on the first substrate;
assembling the first and second substrates, wherein:
the first substrate is placed over the second substrate, or
the second substrate is placed over the first substrate; and
bonding the first substrate and the second substrate to form the substrate, thereby forming an enclosed channel or enclosed cavity comprising the at least one functional nanofiber in the substrate.

A microfluidic device is also provided comprising:

a substrate, wherein the substrate comprises a first substrate and a second substrate bonded together; and

an enclosed channel or enclosed cavity, wherein the enclosed channel or enclosed cavity comprises:
a portion of the first substrate and a portion of the second substrate bonded together, and
at least one functional electrospun nanofiber positioned in the enclosed channel or enclosed cavity.

An enclosed channel or enclosed cavity, wherein the enclosed channel or enclosed cavity comprises:
a portion of a first substrate and a portion of a second substrate bonded together, and
at least one functional electrospun nanofiber positioned in the enclosed channel or enclosed cavity.

### 5.1. Methods for Producing a Channel or Cavity Comprising a Functional Nanofiber

A method is provided for incorporating electrospun nanofibers for sample purification or analyte concentration in a microchannel. A method for producing, in a substrate, an enclosed channel or enclosed cavity comprising at least one functional nanofiber, the method comprising the steps of:

providing a first substrate and a second substrate;

forming a channel or cavity on either the first substrate or the second substrate or on both the first substrate and the second substrate);

electrospinning at least one functional nanofiber on the first substrate;

assembling the first and second substrates, wherein:
the first substrate is placed over the second substrate, or
the second substrate is placed over the first substrate; and

bonding the first substrate and the second substrate to form the substrate, thereby forming an enclosed channel or enclosed cavity comprising the at least one functional nanofiber in the substrate.

The enclosed channel or enclosed cavity can comprise at least one inlet and/or at least one outlet.

As will be evident to the skilled artisan, in various embodiments, the steps of the method can vary in order. For example, in one embodiment, the nanofiber can be electrospun on the first substrate and in a step preceding or following the electrospinning step, a channel or cavity can be formed on the second substrate.

In various embodiments, the first or second substrates can be, e.g., flat, flexible, rough, smooth or patterned.

An enclosed channel or enclosed cavity is also provided, wherein the enclosed channel or enclosed cavity comprises:

a portion of a first substrate and a portion of a second substrate bonded together, and
at least one functional electrospun nanofiber positioned in the enclosed channel or enclosed cavity.

In a preferred embodiment, the enclosed channel or cavity is a microchannel (e.g., a microfluidic channel).

In a specific embodiment, the diameter of the nanofiber is 1-1000 nm.

Polymeric nanofibers such as poly(vinyl alcohol) (PVA) blend nanofibers can be formulated to create variations in fiber surface chemistry for incorporation into the channel (or cavity). The polymeric nanofibers can be electrospun to form patterns around conductive surfaces, e.g., electrodes microelectrodes, on a chip surface, e.g., around gold microelectrodes on a poly(methyl methacrylate) (PMMA) chip surface. The conductive surface can be used to control positioning or patterning of the electrospun nanofibers. These nanofiber patterns can be integrated into polymer-based channels (e.g., microchannels) or cavities to create a functionalized microfluidic system for use in bioanalysis. Spinning conditions and conductive surfaces (e.g., microelectrodes) can be optimized as disclosed herein to enable alignment of the nanofibers across the microchannel. Nanofibers can be used for three-dimensional (3D) coordinated biosensing structures within a functionalized microfluidic system. Nanofibers can be spun onto polymer substrates, e.g., Poly(methyl methacrylate) (PMMA), polycarbonate (PC), polystyrene (PS), Polydimethylsiloxane (PDMS), polyethylene (PE), cyclic olefin copolymer (COC) or other suitable polymers known in the art, agarose, glass, metals, silicon or any other suitable substrate known in the art. In certain embodiments, the substrates can also comprise patterned conductive surfaces or electrodes. Microscale channels or cavities are subsequently placed on top of the nanofibers resulting in the nanofibers positioned or embedded within the channels or cavities in the desired locations.

In one embodiment, polymeric nanofibers can be incorporated into microfluidic structures or devices (e.g., microfluidic substrates, channels, wells or chips) to enhance molecular transport at the fluid flow and bulk material interfaces.

The incorporation of nanofiber in the microfluidic structure or device can confer 100 or more-fold enhanced molecular (or cellular) interactions. The incorporation of nanofiber in the microfluidic structure or device can also allow the creation of a broad range of surface chemistries that cannot otherwise be achieved using current microfabrication materials and methods. The incorporation of nanofiber in the microfluidic structure or device can also allow the creation of well-defined mechanical environments for cells through the geometric arrangement and tailored modulus of nanofibers. Nanofibers are cost-effective and can be produced in the entire range of biological, chemical and mechanical properties proposed without extensive clean room time or additional chemical treatment steps in contrast to the herring bone or pillar-based microfluidic systems.

Electrospinning is an art-known fiber formation process that relies on electrical rather than mechanical forces to form nano and microscale (100 nm to 10 μm) fibers and can be carried out, for example, as described in Section 6.1, Example 1.

The nanofibers disclosed herein can be electrospun directly onto any conductive surface known in the art, including but not limited to conductive polymers, copper, gold, titanium, chromium, platinum, silver or tungsten (wolfram). In one embodiment, the method comprises the step of spinning nanofibers within a microchannel, across the channel and along the channel length, thereby producing three-dimensional (3D) structures with high surface-to-volume ratios within a polymer microchannel.

In another embodiment, the step of electrospinning the at least one functional nanofiber produces the at least one functional nanofiber in a desired orientation. For example, in various embodiments, at least one nanofiber can be positioned or oriented within the enclosed channel or enclosed cavity in a desired orientation that is a direction substantially parallel to, or across the width or transverse diameter of the enclosed channel or enclosed cavity (e.g., parallel to an axis substantially perpendicular to the long(est) axis or length of the channel or cavity).

In other embodiments, the nanofiber(s) can be positioned or oriented in a desired orientation that is substantially parallel to, or along the long(est) axis or length of the enclosed channel or enclosed cavity.

In other embodiments, the nanofiber(s) can be positioned or oriented in a desired orientation that is a random orientation across the length or across the width of the enclosed channel or enclosed cavity.

In other embodiments, the nanofiber(s) can be positioned or oriented in a desired orientation that is a random distribution within the enclosed channel or enclosed cavity).

In other embodiments, the nanofiber(s) can be positioned or oriented in a tuft or mat positioned in the interior (or comprised in) the enclosed channel or enclosed cavity.

In a specific embodiment, a plurality of functional nanofibers is electrospun. In various embodiments, the plurality of electrospun functional nanofibers can be meshed together or physically contacting one another, or preferably, separated in different locations in the interior of the enclosed channel or enclosed cavity, with the positions or orientations as described above.

It will be apparent to the skilled artisan that depending on the configuration of the enclosed channel or enclosed cavity, nanofibers can be positioned so that at a given location, the nanofibers are parallel to a particular axis or landmark in the channel or cavity and at another location, are perpendicular, diagonal, or in another orientation.

In another embodiment, at least one functional nanofiber on the first substrate is positioned partially or in its entirety in a channel or cavity in the first substrate.

In another embodiment, at least one functional nanofiber on the first substrate is positioned partially or in its entirety in functional contact with a channel or cavity in the second substrate upon bonding the two substrates together.

In another embodiment, the at least one spun functional nanofiber connects to at least one of the conductive surfaces.

For example, the method can comprise forming a channel or cavity on a surface of the first substrate. Electrospun fibers can then be positioned across the same surface and during the assembly step, the second substrate can be placed over the first substrate. The first and second substrates are then bonded or sealed, forming an enclosed channel or enclosed cavity comprising the at least one functional nanofiber.

Alternatively, the method can comprise forming a channel or cavity on a surface of the second substrate. Electrospun fibers can then be positioned across the same surface and during the assembly step, the first substrate can be placed over the second substrate. The first and second substrates are then bonded or sealed as described above, forming an enclosed channel or cavity comprising the at least one functional nanofiber.

In either configuration, a conductive surface (e.g., electrode) can be deposited or positioned either on the inner surface (the portion that ends up inside or in the interior of the enclosed channel or cavity) of the first or second substrate or on the outer surface of the first or second substrate. Thus in certain embodiments, the conductive surface is on the exterior surface of the first or second substrate, i.e., on the surface that is opposite the interior surface.

Furthermore, the fibers can be spun across the width of the channel, along the length of the channel (along and in) or randomly. If the fibers are placed across the width (diameter) of the channel, the conductive surface, e.g., the electrode, can be placed ‘parallel’ (along the long axis) of the interior of the channel. If the fibers are positioned along the length (long axis) of the channel or parallel to the long axis, the conductive surface or electrode can be placed across the width/diameter of the channel at an end or terminus (or near an inlet or an outlet) of the channel.

In other embodiments, the conductive surface or electrode is not inside the channel and can be, for example beyond the end of the channel so there is no conductive surface actually within the channel. Alternatively, fibers are desired that are positioned in only a portion of the length of the channel, but aligned with the long axis, the electrodes could be placed near that portion and not at the end or terminus of the channel.

In a preferred embodiment, a plurality of functional nanofibers is electrospun. In various embodiments, the plurality of electrospun functional nanofibers can be meshed together or physically contacting one another, or preferably, separated in different locations in the interior of the enclosed channel or enclosed cavity, with the positions or orientations as described hereinabove.

In another preferred embodiment, although the nanofibers are distributed throughout the channel, they are distributed with a spacing or density so that there is still significant space for fluids and particles to flow through the channel. Suitable spacings, distributions or densities can be calculated and produced using methods known in the art.

Methods for producing aligned nanofibers and for positioning nanofibers patches with specific or desired sizes and shapes are known in the art (see, e.g., Yang H and Dong L. Langmuir; 26 (3):1539-1543). In a specific embodiment, at least one nanofiber is positioned across, along or randomly within the enclosed channel or cavity.

In another embodiment, at least one electrospun functional nanofiber is connected to at least one conductive surface and spans the enclosed channel or cavity.

The method can additionally comprise, between the step of forming a channel or cavity and the step of electrospinning, the step of depositing at least one conductive surface (e.g., microelectrode) on a surface of the first substrate or on a surface of the second substrate. The conductive surface can be deposited on the same surface or on the opposite surface of the substrate to which the nanofibers are attached or the conductive surface can make functional contact with the surface of the substrate.

In specific embodiments, the conductive surface is deposited on an interior surface of the first substrate or the second substrate (i.e., the surface that will subsequently be facing towards the interior or inside the channel) or an exterior surface of the first substrate or the second substrate (i.e., the surface that will subsequently be on the exterior or on the outside of the channel).

In another embodiment, the conductive surface can be glued or otherwise affixed, according to methods known in the art, to a surface of a substrate prior to the electrospinning step. Alternatively, the conductive surface can be microfabricated on the surface of the substrate prior to the electrospinning step. Electrospinning can then be conducted after the substrate has been put into contact with the conductive surface.

If the conductive surface is positioned (or deposited) on the first substrate, the nanofibers are spun onto that substrate rather than the second substrate. If the conductive surface is positioned (or deposited) on the second substrate, the nanofibers are spun onto that substrate rather than the first substrate.

In some embodiments, the conductive surface can be part of the electrospinning apparatus. Also in this embodiment, however, the substrate will first be located in proximity of this conductive surface and subsequently the nanofibers will be spun onto the surface.

In one embodiment, the nanofiber contacts or is connected to at least one of the conductive surface(s).

In another embodiment, the nanofiber does not contact or is not connected to a conductive surface.

In a specific embodiment, at least one conductive surface is adjacent to the channel or cavity.

In another embodiment, at least a first conductive surface and a second conductive surface are deposited. The first conductive surface and the second conductive surface can be positioned, for example, on substantially opposite interior sides, substantially opposite exterior sides, or on an interior side substantially opposite an exterior side, of the enclosed channel or enclosed cavity.

In a specific embodiment, a plurality of conductive surfaces is deposited.

In a preferred embodiment, the members of a plurality of conductive surfaces are all physically or functionally connected to each other, so they are not separate. However, in other embodiments, at least one of the conductive surfaces is separate, i.e., does not physically or functionally connect to another conductive surface.

The conductive surface(s) are used to provide an electrical ground onto which the nanofibers can fall. This electrical ground can also be on the opposite side of the substrate, e.g., a thin polymer sheet; it does not have to be on the side onto which the nanofibers fall. Thus, in certain embodiments a channel, cavity or microfluidic device does not comprise a conductive surface or an electrode after channel/cavity formation or device assembly.

The conductive surface can be deposited using methods known in the art. In a specific embodiment, at least a first conductive surface and a second conductive surface are deposited, wherein the first conductive surface and the second conductive surface are positioned on opposite sides of the enclosed channel or cavity.

In a specific embodiment, the step of depositing at least one conductive surface on a surface of the first substrate or on a surface of the second substrate comprises the step of providing at least one electrode for controlling positioning of the at least one nanofiber. The electrode can control positioning of the nanofiber, e.g., across, along or randomly within the channel or cavity. In another embodiment, the step of providing the at least one electrode comprises patterning at least one electrode adjacent to the channel or cavity.

In one embodiment, the electrode comprises metal or a conductive material. In a specific embodiment, the electrode is a gold electrode.

The first or second substrate can comprise any suitable material for forming microchannels or cavities known in the art. In various embodiments, the first or second substrate channel can comprise Poly(methyl methacrylate) (PMMA), polycarbonate (PC), polystyrene (PS), Polydimethylsiloxane (PDMS), agarose, glass or silicon.

In one embodiment, the nanofibers are conductive nanofibers comprising carbon nanotubes or electroactive or conductive (intrinsically conducting) polymers such as electron-conducting, proton-conducting or ion-conducting polymers, poly(acetylene)s, poly(diacetylene)s, poly(phenylene)s, poly(phenylene vinylene)s, poly(thiophene)s, poly(pyroles)s, poly(aniline)s, and conducting polyrotaxanes. In a specific embodiment, the conductive polymer is PEDOT:PSS (Poly(3,4-ethylenedioxythiophene) poly(styrenesulfonate)). Such conductive nanofibers can be spun and characterized for amperometric and electrochemiluminescence reactions using methods known in the art.

In one embodiment, the nanofiber can comprise two types of polymers, a first (or main) polymer, and at least one second (additive) polymer, are used to prepare electrospinning dopes. In one embodiment, the first (main) polymer can be a mixture of polymers. Preparation of spinning dopes is known in the art and can be carried out, for example, as described in Section 6.1, Example 1. In a preferred embodiment, aqueous conjugated solution(s) of polymers are prepared for use in the electrospinning dopes. In other embodiments, non-aqueous solutions can be used. In a specific embodiment, a polymer can be prepared in a concentrated solution of formic acid for use in an electrospinning dope.

In one embodiment, the first polymer is selected from the group consisting of polyvinyl alcohol (PVA), Poly(lactic acid) (PLA), cellulose nitrate, cellulose acetate, polyamide, polyethylene oxide (PEO) and polyacrylonitrile (PAN), collagen, other extracellular matrix (ECM) components known in the art and mixtures thereof.

In another embodiment, the at least one second (additive) polymer is selected from the group consisting of Hexadimethrine bromide (Polybrene), Poly(methyl vinyl ether-alt-maleic anhydride) (Poly(MVE/MA), Poly(3,4-ethylenedioxythiophene) poly(styrenesulfonate) (PEDOT:PSS), DNA, RNA, PNA, peptides, oligosaccharides, naturally occurring polymers and mixtures thereof.

In specific embodiments, the nanofiber is a PVA/Polybrene or a PVA/Poly(MVE/MA) nanofiber. In another specific embodiment, the nanofiber is a collagen-coated nanofiber.

In one embodiment, the nanofiber comprises positive charges and/or negative charges on a surface of the nanofiber. The additive polymer can be added to the spinning dope to fabricate positively and negatively charged nanofibers.

In another embodiment, the nanofiber comprises a chemical functionality on a surface of the nanofiber, e.g., a hydrophobic or hydrophilic nanofiber surface, a nitrate group at the nanofiber surface or resistance to non-specific binding.

In a specific embodiment, nanofibers can be prepared from a polymer such as cellulose nitrate or cellulose nitrate acetate, to provide available nitrate groups at the fiber surface.

In another embodiment, the nanofiber comprises a functional group on a surface of the nanofiber that can be protonated or deprotonated. The functional group can be selected from the group consisting of amine, nitrate, carboxyl, hydroxyl, peroxide, sulfhydryl, maleimide, reactive group and protected reactive group. Any reactive group or protected reactive group can be used.

In another embodiment, biorecognition or biological sensing (biosensor) elements can be added to the electrospinning dope prior to the electrospinning of conductive or non-conductive nanofibers. The biorecognition element can be used for identification, isolation and/or interaction with an analyte of interest, and is the interface between the sample and the nanofiber. The intrinsic biological selectivity of the biorecognition element confers selectivity to the nanofiber. Biorecognition element can be derived from natural sources, e.g. bacteria, plant or animal, but can also be generated artificially by molecular imprinting techniques. Any suitable biorecognition element known in the art can be used, including, but not limited to, antibodies, aptamers, peptides, proteins (e.g., binding proteins, enzymes and apoenzymes), binding phages, nucleic acids (e.g., nucleic acid probes such as RNA or DNA probes), receptors, molecular imprinted polymers, and other small molecules with biorecognition properties.

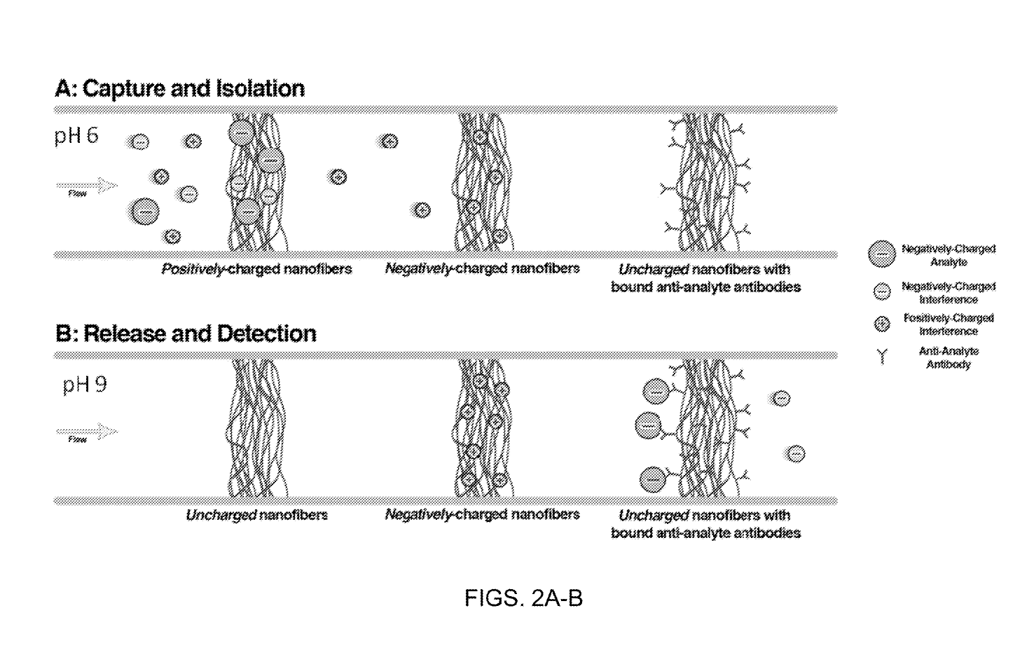

Surface-charged nanofibers can be used as an alternative to modifying the surface of a nanofiber with biorecognition elements. In one embodiment, polymers can be added to the electrospinning dope that comprise negatively charged chemical groups (e.g., poly maleic anhydride) or positively charged chemical groups (e.g., polybrene) or other chemically active groups as disclosed herein, prior to the electrospinning of conductive or non-conductive nanofibers. Surface-charged nanofibers can concentrate target biomolecules via electostatic attraction between charges on the nanofiber surface and the counter charge of the target material, thus improving detection sensitivity. These positive or negative charges can function in the isolation or purification of an analyte to be isolated. See FIGS. 2A-B.

Nanofibers can be electrospun to mimic the fibrous proteins in a native extracellular matrix (see, e.g., Ma Z, Kotaki M, Yong T, He W, and Ramakrishna S. Biomaterials 2005; 26 (15):2527-2536). The charge storage performance for electrospun nanofibers can be characterized, e.g., the surface charging potential of the candidates for filter and sensing applications (see, e.g., Ignatova M, Yovcheva T, Viraneva A, Mekishev G, Manolova N, and Rashkov I. European Polymer Journal 2008; 44 (7):1962-1967; Kravtsov A, Brunig H, Zhandarov S, and Beyreuther R. Advances in Polymer Technology 2000; 19 (4):312-316; Lovera D, Bilbao C, Schreier P, Kador L, Schmidt H-W, and Altstaedt V. Polymer Engineering & Science 2009; 49 (12):2430-2439). Functional groups can be introduced into the nanofibers polymer and their surface properties (see, e.g., Terada A, Yuasa A, Kushimoto T, Tsuneda S, Katakai A, and Tamada M. Microbiology (Reading, United Kingdom) 2006; 152 (12):3575-3583). Desired ligands can also be immobilized on the nanofiber, similar to immobilization on an affinity membrane, to permit the purification of molecules based on their physical/chemical properties (see, e.g., Ma Z, Kotaki M, and Ramakrishna S. Journal of Membrane Science 2005; 265 (1-2):115-123).

Nanofibers incorporated into microchannels provide a broad range of chemical, biological and mechanical functionality and can increase analyte-surface interactions by at least 100-fold over state-of-the-art microfluidic devices. These increased interactions can be harnessed (a) to improve micro total analysis systems (microTAS) for clinical diagnostics; and (b) to design novel microfluidic in vitro models to study cancer cell movement.

Table 1 summarizes desired properties of the nanofibers and the materials that are used to spin nanofibers delivering each of those properties. A number of methods known in the art can be used to create each type of fiber.

TABLE 1
Nanofiber properties and materials

| | | |
|---|---|---|
| CHEMICAL | Hydrophobic | Polylactide (PLA) fiber |
| | surface | Polyamide (PA) fiber |
| | | Cellulose acetate fiber (CA) |
| | Hydrophilic surface | Polylactide/polyethylene |
| | | glycol (PLA/PEG) blend fiber |
| | | Polyvinyl alcohol (PVA) fiber |
| | Nitrate group at | Cellulose nitrate polymer (CN) |
| | surface | fiber |
| | | Cellulose nitrate/acetate mixed |
| | | ester fiber (CNA) |
| | Resist non-specific | Polylactide (PLA) + tri-block |
| | binding | co-polymer |
| BIOLOGICAL | Biotinylated surface | PLA + biotin fiber |
| | | PVA + biotin fiber |
| | | PLA/PEG-g-biotin blend fiber |
| | Collagen fiber/ | Collagen fiber |
| | surface | Sheath/core collagen/PLA |
| | | fiber |
| MECHANICAL | Negative surface | PVA fiber |
| | charge (δ⁻) | PLA fiber |
| | | PVA/Polymaleic anhydride |
| | | blend fiber |
| | Positive surface | PVA/Polybrene blend fiber |
| | charge (δ⁺) | |
| | Variable modulus | Incorporate carbon nanotubes |
| | | with fiber or fiber core |

The method for producing a bonded channel or cavity comprising at least one functional nanofiber comprises the step of bonding the first and second substrates, thereby forming a bonded channel or cavity comprising the at least one functional nanofiber. The bonded channel can comprise an inlet and an outlet through which fluid can flow through the channel. Thus, although the top and bottom substrates are bonded together, fluids flow through the channel. In one embodiment, the bonding step can be irreversible or reversible. In another embodiment, the bonded channel or cavity can be irreversibly or reversibly bonded.

### 5.2. Microfluidic Devices Comprising an Enclosed Channel or Enclosed Cavity that Comprises Functional Electrospun Nanofibers

A microfluidic device is also provided comprising an enclosed channel or cavity comprising at least one functional electrospun nanofiber. In one embodiment, the microfluidic device comprises:

a substrate, wherein the substrate comprises a first substrate and a second substrate bonded together; and

an enclosed channel or enclosed cavity, wherein the enclosed channel or enclosed cavity comprises:

a portion of the first substrate and a portion of the second substrate bonded together, and

at least one functional electrospun nanofiber positioned in the enclosed channel or

enclosed cavity.

The enclosed channel or enclosed cavity can comprises a portion of a first substrate and a portion of a second substrate bonded together, and at least one functional electrospun nanofiber positioned in the enclosed channel or enclosed cavity. In a preferred embodiment, the enclosed channel or enclosed cavity comprises an inlet and/or an outlet.

In one embodiment of the device, the enclosed channel or enclosed cavity comprises a channel or cavity formed in the first substrate and/or the second substrate prior to the bonding of the first substrate and the second substrate.

In another embodiment of the device, at least one functional nanofiber is positioned within the enclosed channel or enclosed cavity in:
(a) an orientation or direction that is substantially parallel to, or across the width or transverse diameter of the enclosed channel or enclosed cavity or that is substantially parallel to, or along the long (or longest) axis or length of the enclosed channel or enclosed cavity,
(b) a random orientation across the length or across the width of the enclosed channel or enclosed cavity,
(c) a random distribution within the enclosed channel or enclosed cavity, or
(d) a tuft or mat positioned in the interior (or comprised in) the enclosed channel or enclosed cavity.

In another embodiment, the device additionally comprising at least one conductive surface.

In another embodiment, a step of purifying, isolating, concentrating and/or detecting a sample or analyte of interest is conducted in the enclosed channel or enclosed cavity.

Fabrication of electrode chips and microchannels can be carried out, for example, as set forth in Section 6.1, Example 1. An electrode array can be prepared on a substrate (e.g., PMMA) to fabricate patterned nanofibers for incorporation in a microchannel.

In one embodiment, to provide electrodes for controlling positioning of the nanofiber across the microchannel, a process for patterning Au electrodes on PMMA using gold-thiol chemistry can be used (Nugen Sam R, Asiello Peter J, Connelly John T, and Baeumner Antje J. Biosensors & bioelectronics 2009; 24 (8):2428-2433). In another embodiment, the method can be modified to use a Cr adhesion layer. Microchannels (e.g., comprising PMMA) can be formed, for example by a hot embossing process using a copper template (Nugen S R, Asiello P J, and Baeumner A J. Microsystem Technologies 2009; 15 (3):477-483).

### 5.3. Characterization of Nanofibers Incorporated into Channels and Cavities

Solvent bonding of the nanofibers to the channel surfaces can be assessed using methods known in the art and the strength of the nanofiber attachment can be measured.

Functional bionanofibers can be characterized physically using a variety of spectroscopy and microscopy techniques as well as tensile testing techniques to confirm successful incorporation of biological molecules, effect of this incorporation on fiber morphology and mechanical properties and to determine the location of the biological molecules within the fibers. For example, X-ray photoelectron spectroscopy (XPS) and Fourier transform infrared spectroscopy (FTIR) can be used to characterize the electrospun polymeric nanofibers.

Nanofibers spun into microchannels maintain their morphologies during fluid flow. The nanofibers can be characterized with respect to their biological recognition ability using methods known in the art, e.g., liposome hybridization and binding assays.

### 5.4. Uses of Enclosed Channels or Enclosed Cavities Comprising Functional Nanofibers

The nanofibers disclosed herein can be incorporated into microfluidic structures or devices to enhance molecular transport at the fluid flow and bulk material interfaces. The advantages of the nanofiber incorporation include: 1) 100 or more fold enhanced molecular (or cellular) interactions; 2) ability to create a broad range of surface chemistries that cannot otherwise be achieved using current microfabrication materials and methods; 3) ability to create well-defined mechanical environments for cells through the geometric arrangement and tailored modulus of nanofibers. Nanofibers are cost-effective and can be produced in a wide range of biological, chemical and mechanical properties without extensive clean room time or additional chemical treatment steps in contrast to the herring bone or pillar-based microfluidic systems.

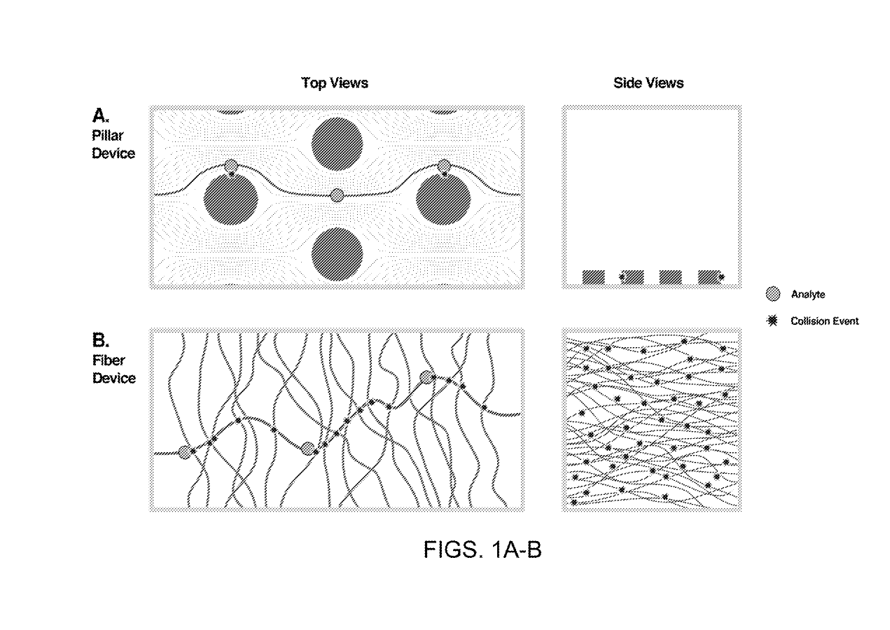

One advantage of a nanofiber-embedded bioanalytical microsystem is enhanced molecular or cellular interactions at the flow bulk material interface. As shown in FIGS. 1A-B, nanofibers distribute throughout a channel providing contact points for molecular interaction across the entire channel volume. In a simplified collision model (molecules get absorbed by a surface upon contact), the number of molecules absorbed in a given time and a given volume is proportional to the surface to volume ratio (total surface available for molecular collision divided by the total volume of the microchannel) of the system. Comparing a matrix of 10×10×10 μm pillars with 10 μm spacing with the same volume of nanofibers (200 nm diameter) spun throughout the channel, the nanofiber microsystem provides 100× larger surface, thus enhancing the molecule surface collision rate by 100 times. In addition, the nanofibers distribute their surface throughout a volume 10× larger than the volume reached by the pillar structures, increasing the probability of impact by molecules or particles carried in any part of a laminar flow. Collision rates are of utmost importance in microfluidic devices for biological applications since biological molecules need to interact via surface contact for reactions such as antigen-antibody binding, hydrophobic and electrostatic interactions to occur.

Another advantage of a nanofiber-embedded bioanalytical microsystem is enhanced number of available surface chemistries for bioanalytical microsystems. Surface chemistry within microfluidic devices is useful for bioanalysis. Specific immobilization of biorecognition elements such as antibodies and DNA probes at appropriate densities are as important as the repelling of interfering substances from the same surfaces. Current microfluidic device designs take advantage of reactive groups including —NH2, —COOH, —OH, —CHO on polymer substrates such as Poly(methyl methacrylate) (PMMA), polycarbonate (PC), polystyrene (PS), or Polydimethylsiloxane (PDMS), and creation of highly reactive peroxides with special plasma treatments.

In one embodiment, additional surface treatments can create tethered structures and dendrimers on the polymer substrates which increase immobilization efficiencies significantly. In current state-of-the-art microfluidic systems, one treatment is used for the entire device or for an entire channel length unless complex functionalization strategies via separate channels and laser-induced treatments are performed. The polymer nanofibers disclosed herein not only increase the variation of surface chemistries available, but also enable an easily defined localization of a specific surface chemistry. Nanofibers can be spun into specific locations within microchannels and create different surface chemistries in different segments of a small channel via very simple process steps.

As an example, for microTAS reaction processes such as filtration, purification, and capture, multiple chemistries need to be incorporated within a single channel at distinct locations. FIG. 2A illustrates a single channel containing three types of nanofiber surfaces at specific locations: positively charged, negatively charged and anti-body labeled. As a test fluid flows through this system, charged interferences are selectively removed and the analyte is concentrated. Subsequently, a lower pH buffer solution flows through the same channel, the buffer neutralizes the charge on the positively charged fibers and releases the concentrated analyte for specific recapture and the antibody labeled detection point (FIG. 2B). Thus, nanofibers can be used to increase surface area and increase collision rates, and also to provide a large number of surface chemistries in distinct locations of the microchannel. Fluid flow along the microchannel transports the target analyte from one “nanofiber processing location” to the next. These three main factors of surface chemistry, surface area and enhanced collision rates, improves a microTAS with significantly faster, simpler and more accurate positive isolation and concentration of an analyte out of its sample with subsequent sensitive detection.

The methods provided herein can be used to create a well-defined mechanical microenvironment for biological applications. Nanofibers can be patterned into microfluidic devices in well-defined geometries. Such capability is important for many biological applications

Through the integration of nanofibers into microchannels, increased collision rates, increased surface area and a variety of localized and three dimensional surface chemistries can be achieved that overcome the limitations of existing microfluidic devices, in particular the diffusion limited transport. The integration of nanofibers into microfluidic channels can provide new capabilities of microfluidic devices such as microTAS for multi-analyte sensing or separation within a single microfluidic channel, microfluidic in vitro models with controlled physical properties (e.g. fiber orientation and stiffness) for cellular level studies leading to understanding of underlying cellular responses; enhanced mixing through the three dimensional arrangement of the fibers within the channels. Each different fiber chemistry can be aligned and patterned within a channel at a specified density. The incorporation of nanofibers allows straightforward, flexible and inexpensive production methods that do not require significant clean room time, which is an advantage when producing a microfluidic device on commercial scales.

The quality of the analytical and quantitative signal of a microTAS relies heavily on the ability to positively isolate the analyte from a complex matrix and interfering substances. The abundance of surface chemistries available through electrospun nanofibers combined with the ability to place multiple chemistries along one microfluidic channel, provides new strategies for sample preparation not possible in typical microTAS devices. The nanofibers can, in addition, assist in blocking out interferences and hence increase the signal-to-noise ratios of the microTAS. Lastly, nanofiber surface chemistries can be exploited for targeted immobilization of biorecognition elements such as antibodies and DNA probes.

The enclosed channels or cavities incorporating functional nanofibers, microfluidic structures comprising these sealed channels or cavities incorporating functional nanofibers, and methods for producing an enclosed channel or cavity comprising at functional nanofibers, as disclosed herein, are applicable to vast areas of biomedical, biological, and environmental research utilizing microfluidic devices. Functional nanofibers bonded in microchannels have a variety of uses. They can be used as bioseparators, electrodes, 3D guiding lines and concentrators and can be combined with nanofibers with various properties, e.g., negative or positive surface charges, hydrophobic or hydrophilic surface, etc. They can be used to mimic in vivo systems s leading to rapid and inexpensive point of care disease detection and greater insight into disease progression.

Nanofibers embedded with the functional polymers can exhibit a charged surface so that these fibers can be used for 3D coordinated biosensing structures within a functionalized microfluidic system.

Medical diagnostics, food safety, biosecurity and a clean and safe environment rely on sensing devices to identify biological molecules or chemical hazards before they impact our health, safety and security. Sensors employing the nanofibers and/or microfluidic channels with incorporated nanofibers can be employed in such sensing devices.

Test kits used by diabetics or the home pregnancy tests are good examples of highly successful and relevant biosensors. Their world-wide use improves lives of patients and women in the world, and means multi-billion dollar businesses. With improved technologies and innovation easy-to-use sensors can also become available for more difficult detection problems including cancer, diseases, food-pathogens and toxins, biothreat agents, etc. Adding nanofibers to lab-on-a-chip biosensors targeting each of these application can be used to produce simple-to-use, inexpensive and highly effective tests for such detection.

Using the method disclosed herein, nanofibers with easily re-configurable chemical, biological and physical properties can be incorporated and combined into arrays within microfluidic devices. Nanofibers within microfluidic devices can be used, for example, in microfluidic total analysis systems for Cholera toxin and Cryptosporidium parvum oocysts, and for microfluidic in vitro models for cancer cell migration, to name but a few.

The following examples are offered by way of illustration and not by way of limitation.

### 6. EXAMPLES

### 6.1. Example 1

### Electrospun Nanofibers for Microfluidic Analytical Systems

In this example, poly(vinyl alcohol) (PVA) blend nanofibers formulated to create variations in fiber surface chemistry were electrospun to form patterns around gold microelectrodes on a poly(methyl methacrylate) (PMMA) chip surface. These nanofiber patterns were integrated into polymer-based microfluidic channels to create a functionalized microfluidic system with potential applications in bioanalysis. Spinning conditions and microelectrodes were optimized to enable an alignment of the nanofibers across the microfluidic channel. X-ray photoelectron spectroscopy (XPS) and Fourier transform infrared spectroscopy (FTIR) were used to characterize the electrospun fibers and the results demonstrated that functional nanofibers were successfully spun from the polymers. Nanofibers spun into the microfluidic channel maintained their morphologies during fluid flow at linear velocities of 3.4 and 13.6 mm/s Nanofibers embedded with the functional polymers exhibited a charged surface so that these fibers can be used for 3D coordinated biosensing structures within a functionalized microfluidic system.

### 6.1.1. Introduction

In the area of bio-analytical sensors, detection systems have been miniaturized to take advantage of small feature sizes with low fluid consumption, faster analysis, and easy portability Lab-on-a-chip devices integrate sample preparation and detection steps into one system and are applied in many clinical, environmental and food safety related industries. Continuous improvement and research is being carried out not only in the improvement of biosensors but also of the sample preparation steps. Nanofibers can be used, for example, as selective filter media and for specific capture of analytes from fluids. Nanofibers can be electrospun with a broad range of chemically active surfaces (Kotek R. Polymer Reviews 2008; 48 (2):221-229; Huang Z-M, Zhang Y Z, Kotaki M, and Ramakrishna S. Composites Science & Technology 2003; 63 (15):2223) and biologically active surfaces (Nisbet D R, Forsythe J S, Shen W, Finkelstein D I, and Home M K. Journal of Biomaterials Applications 2009; 24 (1):7-29; Botes M and Cloete T E. Critical Reviews in Microbiology 2010; 36 (1):68-81; Kriegel C, Arrechi A, Kit K, McClements D J, and Weiss J. Critical Reviews in Food Science & Nutrition 2008; 48 (8):775-797; Schiffman J D and Schauer C L. Polymer Reviews 2008; 48 (2):317-352) potentially useful in separation and capture of target analytes. Nanofibers have also been utilized to improve targeted properties in such application areas as tissue engineering scaffolding (Agarwal S, Wendorff J H, and Greiner A. Advanced Materials (Weinheim, Germany) 2009; 21 (32-33):3343-3351; Dalton P D, Joergensen N T, Groll J, and Moeller M. Biomedical Materials (Bristol, United Kingdom) 2008; 3 (3):034109/034101-034109/034111; Freed L E, Engelmayr G C, Jr., Borenstein J T, Moutos F T, and Guilak F. Advanced Materials (Weinheim, Germany) 2009; 21 (32-33):3410-3418.), nanofibrous membrane biosensors (Li D, Frey M W, and Baeumner A J. Journal of Membrane Science 2006; 279 (1/2):354-363; Ye P, Xu Z-K, Wu J, Innocent C, and Seta P. Biomaterials 2006; 27 (22):4169-4176) and electronic sensors (Wang G, Ji Y, Huang X, Yang X, Gouma P-I, and Dudley M. Journal of Physical Chemistry B 2006; 110 (47):23777-23782; Wang X, Drew C, Lee S-H, Senecal K J, Kumar J, and Samuelson L A. Nano Letters 2002; 2 (11):1273-1275). The nanofibers for these applications have been fabricated by electrospinning, a technique through which fibers of a range of diameters from micrometers to nanometers can be produced from an electrically driven jet of polymeric fluid (Reneker D H and Yarin A L. Polymer 2008; 49 (10):2387-2425).

In this example, hydrophilic functional nanofibers with charged surfaces suitable for bio-applications were developed, incorporated into microfluidic channels and the durability of those fibers within the channels demonstrated. Gold electrodes were patterned adjacent to the microfluidic channels to control for the positioning of the nanofibers across the channels. Nanofibers used in this study were designed to be hydrophilic with either partial positive (δ⁺) or partial negative (δ⁻) charge at the fiber surface under flow conditions in the microfluidic channel.

The phenomenon of a formation of charged surfaces at the interface between a solid and an electrolyte is well-known (Tandon V and Kirby Brian J. Electrophoresis 2008; 29 (5):1102-1114). These charges arise either from surface ionization (group dissociation) or ion adsorption. The aim of this example was to develop hydrophilic fibers with charged surfaces suitable for bio-applications. Highly hydrolyzed PVA polymers (>99%) were blended with functional polymers targeted to provide a polarizable surface. PVA is especially useful for the materials in the bio-analysis system because it can be processed from hot water eliminating risk that the fabricated PVA nanofiber webs contain any toxic solvents which might interfere with analytes in solution. The resulting electrospun nanofibers are stabilized by strong intermolecular hydrogen bonding (Chang I-S, Kim C-I, and Nam B-U. Process Biochemistry (Oxford, United Kingdom) 2005; 40 (9):3050-3054) and do not swell significantly or dissolve in the room temperature aqueous solutions used for bioanalysis. Two types of functional polymers, Hexadimethrine bromide (Polybrene) and Poly(methyl vinyl ether-alt-maleic anhydride) (Poly(MVE/MA)), which have positive and negative functional groups, were blended with PVA in the electrospinning dope to provide additional functionality. The amine groups or carboxyl groups in the functional polymers can be protonated or deprotonated in the pH of the solutions. The protonation or deprotonation of the functional polymers usually results in positive or negative charges on the fiber surface, incorporating the functional polymers. The charged surfaces on the electrospun fibers were induced when they met with the aqueous solutions owing to the dissociation (ionization) of the functional groups on the surface or the adsorption (protonation) of ions from the solutions. XPS and FTIR were employed to detect and characterize the incorporation of Polybrene and Poly(MVE/MA) in the electrospun fibers.

Nanofiber alignment within the microfluidic channels was easily controlled during the spinning process and was not disrupted by the assembly of the full microfluidic device. Nanofiber stability in the microfluidic channels before and after high rates of fluid flow was evaluated by regular light microscopy. The effluent was collected from the microfluidic channels and analyzed using FTIR and H-NMR to confirm nanofiber durability.

### 6.1.2. Experimental Section

Materials

PVA polymer was purchased from Polysciences, Inc. (Warrington, Pa., USA). This polymer, with a molecular weight of 78,000, is 99.7% hydrolyzed to obtain the same number of corresponding hydroxyl groups as the degree of polymerization. The functional polymers, whose charges would be activated with ions in the aqueous solutions, were purchased from Sigma-Aldrich. The positively charged Polybrene is soluble in water, and its molecular weight is 4,000˜6,000. The negatively charged Poly(MVE/MA) is also soluble upon hydrolysis, and its molecular weight is 216,000. To reduce the surface tension of water and to retard the gelation of PVA in the spinning dope, adding a nonionic surfactant to the spinning dope is recommended (Yao L, Haas T W, Guiseppi-Elie A, Bowlin G L, Simpson D G, and Wnek G E. Chemistry of Materials 2003; 15 (9):1860-1864). Nonionic surfactant Triton X-100 (p-tertiary-octylphenoxy polyethyl alcohol) was purchased from Sigma Aldrich Company. Distilled (DI) water was used as a solvent to dissolve both PVA polymers and functional polymers.

Preparation of Electrospinning Dopes

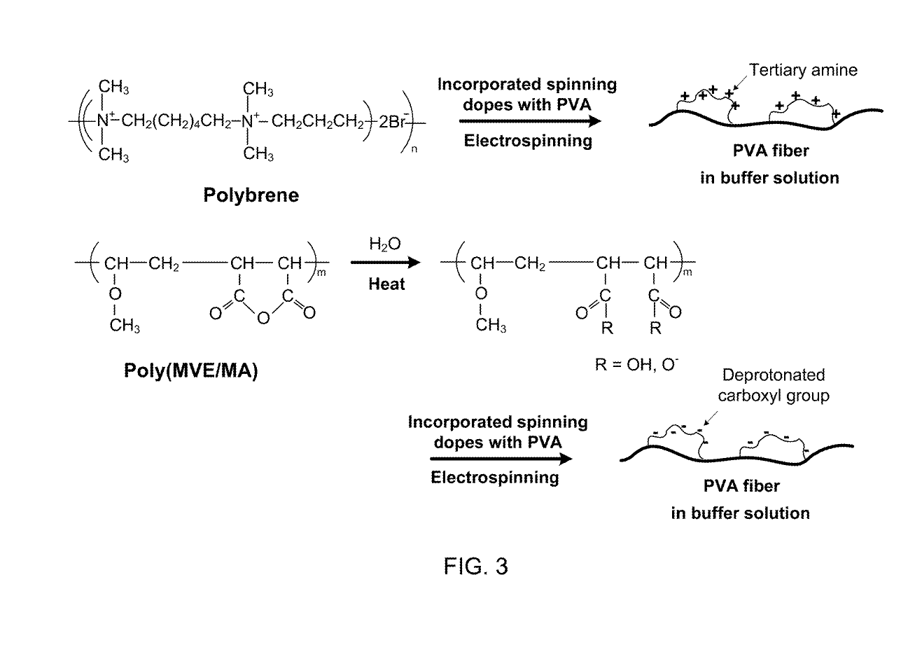

Two types of polymers, the PVA and the additive polymer, were used for aqueous conjugated solutions to prepare the spinning dopes. Polybrene or Poly(MVE/MA) polymers were utilized as additive polymers to fabricate positively and negatively charged nanofibers. All procedures for preparing the spinning dopes are described as follows. At first, 10 wt % PVA polymers were dissolved in DI water at an oven temperature of 95° C. for four hours. Then, a solution of Polybrene over PVA polymer (10/90 wt %/wt %) was also dissolved in DI water at room temperature. After the PVA solution was cooled to room temperature, the dissolved additive polymers were poured into PVA solution and then mixed together with a vortex for two minutes. Finally, Triton X-100 was added to the mixtures in a concentration between 0.5 and 1.0 wt/wt solution % and agitated with a vortex for two minutes and Arm-Shaker for one hour to make a homogenous spinning dope for electrospinning positively charged nanofibers. Poly(MVE/MA) was utilized to fabricate the negatively charged nanofibers. The maleic anhydride groups in Poly(MVE/MA) are derivatives of carboxylic acids, as shown in FIG. 3. By hydrolyzing the maleic anhydride, which is treated in DI water at 90° C. for 15 minutes, Poly(MVE/MA) can be dissolved in water. As stated earlier, all the procedures for forming spinning dopes and spinning the fibers using Poly(MVE/MA) are the same as for Polybrene. Polymer compositions of typical spinning dopes (without water) were; PVA/triton X-100: 89/11, PVA/Polybrene/triton X-100: 82/8/10, PVA/Poly(MVE/MA)/triton X-100: 82/8/10.

Fabrication of Nanofibrous Webs

A 5 mL plastic syringe with an 18 gauge needle (inner diameter: 0.84 mm) was loaded with the prepared dope. A high voltage power supply (Gamma High Voltage Research Inc., FL) was used to apply a positive charge to the needle. To collect the electrospun fiber webs, either a grounded copper plate covered by aluminum foil or a grounded chip with electrodes was used. A micropump (Harvard Apparatus, Holliston, Mass.) was used to infuse the solution and to eject it toward to the collector. A voltage of 12 kV was maintained at the tip of the needle. The distance between the collector and the needle tip was set at 10˜15 cm, and a constant flow rate for the solution was set to 0.54 ml/hour. Electrospinning was maintained at room temperature.

Fabrication of Electrode Chip and Microfluidic Channel

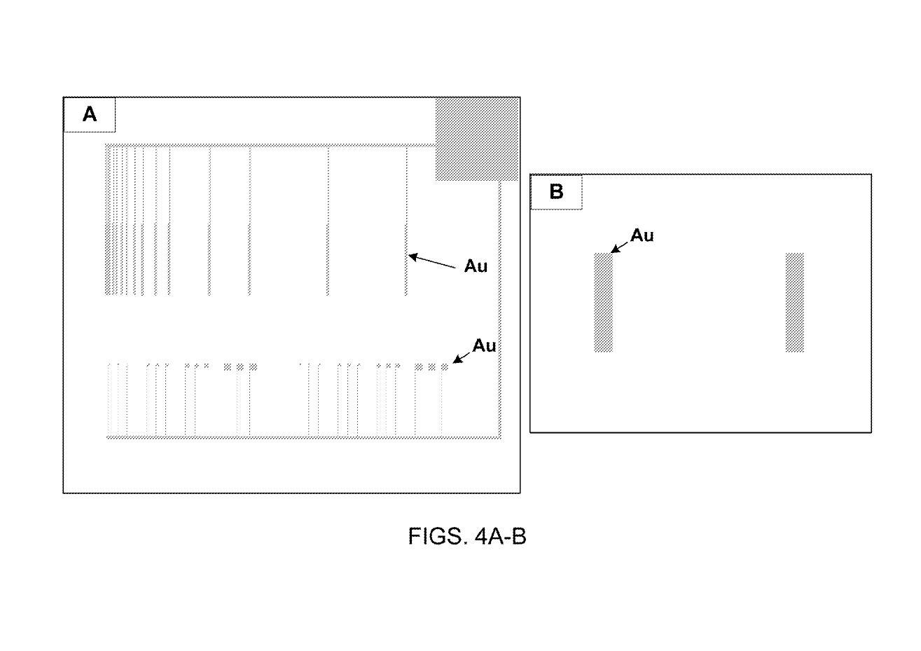

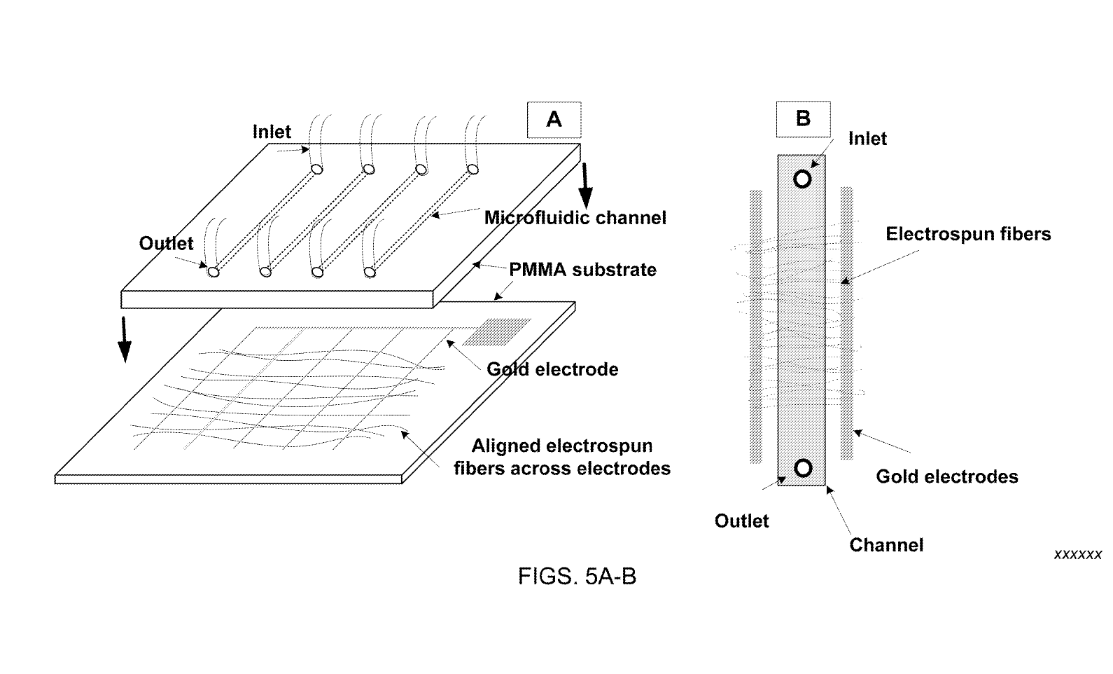

Electrode arrays were prepared on PMMA to fabricate patterned nanofibers for incorporation in a microfluidic channel. A process for patterning Au electrodes on PMMA using gold-thiol chemistry has been described previously (Nugen Sam R, Asiello Peter J, Connelly John T, and Baeumner Antje J. Biosensors & bioelectronics 2009; 24 (8):2428-2433), but the use of a Cr adhesion layer was employed here instead. PMMA surfaces were cleaned by sonication for 5 minutes in 2-propanol and treated with UV light. A CHA Mark 50 evaporator (CHA Industries, Freemont, Calif.) was used to coat the PMMA with 10 nm Cr followed by 200 nm Au at deposition rates of 0.1 nm/s and 0.25 nm/s, respectively. A positive photoresist (Shipley 1813, Shipley, MA, USA) was then spun on the gold-coated PMMA at 3000 rpm for 30 seconds. The photoresist was UV exposed for 11 seconds through a mask containing the electrode pattern using a contact aligner (ABM, Scotts Valley, Calif.) and developed for one minute in MF-321 developer (Shipley Co., Marlborough, MA). The exposed Au was then etched away by Au etchant type TFA (Transene, Danvers, MA) for one minute and the underlying Cr layer was etched away by Cr etchant (Cyantek, Freemont, Calif.) for 15 seconds to form the electrodes. Lastly, 100 mM NaOH was used to remove the photoresist from the electrodes. As shown in FIG. 4A, the electrodes were designed with varying gaps between neighboring electrodes. The following feature sizes were studied: gap size (0.1, 0.2, 0.3, 0.5, 1, 5, 10 mm) and square size (50, 100, 250, 500 μm). All the electrodes had a width of 100 μm and were connected to the corner square with 100 μm leads. The height of the electrode was 200 nm at Au and 10 nm at Cr. As illustrated in FIG. 4B, electrodes with a gap of 15 mm and electrode width of 1 mm or 2.5 mm were designed and employed to align electrospun fibers over longer distances. Microfluidic PMMA channels were formed by a hot embossing process using a copper template as previously described (Nugen S R, Asiello P J, and Baeumner A J. Microsystem Technologies 2009; 15 (3):477-483). Briefly, the channel design on the copper template was formed by patterning with an epoxy-based resist (KMPR 1050, Micro-Chem. Corp., Newton, Mass.) and copper electroplating. The channels (length 12.5 mm, width 0.66 mm, and depth 37 μm) were embossed in PMMA at 130° C. and 5000 lbs in a hot press (Carver, Wabash, Ind.) for 10 minutes, and 0.78 mm holes were drilled so that inlet and outlet tubing could be inserted. The channels were then sealed with UV-assisted thermal bonding (Tsao C W, Hromada L, Liu J, Kumar P, and DeVoe D L. Lab on a chip 2007; 7 (4):499-505). The PMMA embossed channels were UV treated for 10 minutes using a UVO-Cleaner Model 144AX (Jelight, Irvine, Calif.) and brought into contact with a PMMA surface containing patterned nanofibers. The surfaces were then bonded by pressing for 10 minutes at 85° C. and 5000 lbs in order to form channels containing nanofibers (see FIGS. 5A-B). Finally, tubing was glued into the channel inlets and outlets to allow access for a syringe pump.

Characterization of Nanofibrous Membrane

Scanning Electron Microscopy (SEM)

The morphology of all electrospun fibrous webs was evaluated with a Leica 440 scanning electron microscope (SEM) after the fiber webs were coated with Au—Pd. Image analysis software (ImageJ 1.41) was used to measure the electrospun fiber diameter.

Testing Nanofibers in Microfluidic Channels

Plain deionized (DI) water was injected through a channel using a syringe pump at 5 and 20 μL/min for 5 min. The effluent was collected to analyze whether the incorporated electrospun fibers were dissolved or not during fluid flow. To make the simulated solutions, the electrospun fibers were dissolved in DI water at 1.0, 0.1, and 0.01 wt % PVA over water. A vial containing DI water and electrospun nanofibers was left in an oven of 65° C. for 6 hours for the preparation of three simulated solutions so that FTIR and NMR could be used to compare the effluent.

FTIR and NMR Measurement

The electrospun fibers were characterized using FTIR and found to be 800 to 3800 cm⁻¹ with a 4 cm⁻¹ resolution. To analyze the effluent and the simulated solutions, ¹H spectra were recorded with an Inova 400 NMR instrument operating at 400 MHz at room temperature, and FTIR was used to measure the effluent and the simulated solutions.

XPS Measurement

XPS experiments were carried out using a model SSX-100 ESCA system with Al Kα radiation (1486.6 eV). XPS analyzes photoelectrons that escape only from the top few mono-layers of a surface making it a very surface-sensitive technique and appropriate for detecting functional groups on the surface of fibers. The operating pressure of the analyzer chamber was about 2×10⁻⁹ torr. The X-ray spot size was 1 mm×2 mm and photoemission electrons were collected with an emission angle of 55 degrees. Typical analysis depths were ˜5 nm and survey spectra were collected into a hemispherical analyzer using a pass energy of 150 V. The binding energy (BE) values were calculated relative to the C (1s) photoelectron peak at 285.0 eV. Three different locations on each sample were measured to ensure reproducibility.

### 6.1.3. Results and Discussion

Incorporation of Functional Polymers in PVA Nanofibers

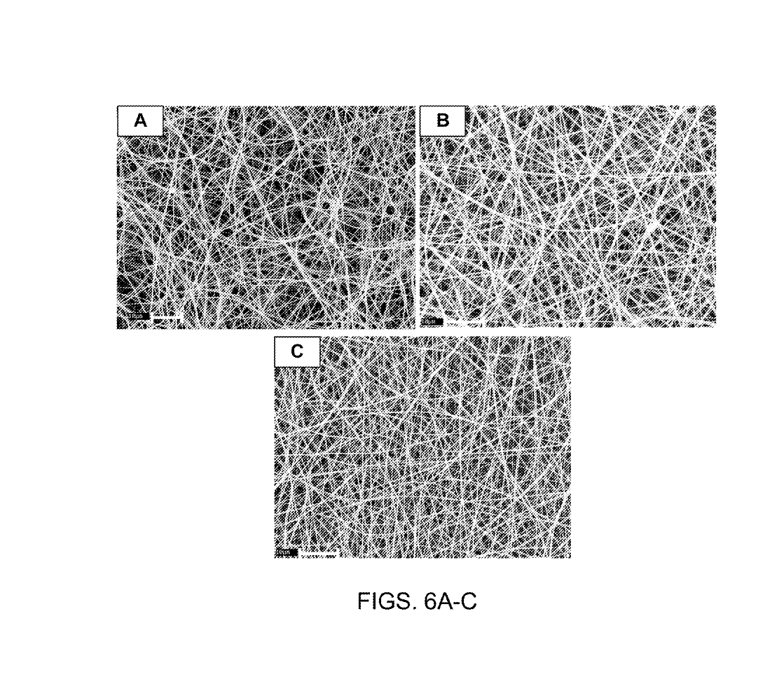

All of the prepared spinning dopes were effectively electrospun on aluminum foil, and as shown in FIGS. 6A-C, the electrospun nanofibers showed good morphology without beads on their fiber surface. Although the prepared solutions were subjected to some variation in spinnability, the diameters and morphologies of the electrospun fibers were very similar; the diameters of the pure PVA fibers ranged from 350 nm to 450 nm, the PVA/Polybrene fibers from 450 nm to 550 nm, and the PVA/Poly(MVE/MA) fibers from 300 nm to 400 nm. Fiber diameters were sensitive to electrospinning conditions and could be altered slightly by such changes in the electrospinning voltage and the distance between the needle and collector.

Examination of Functional Groups within Fibers

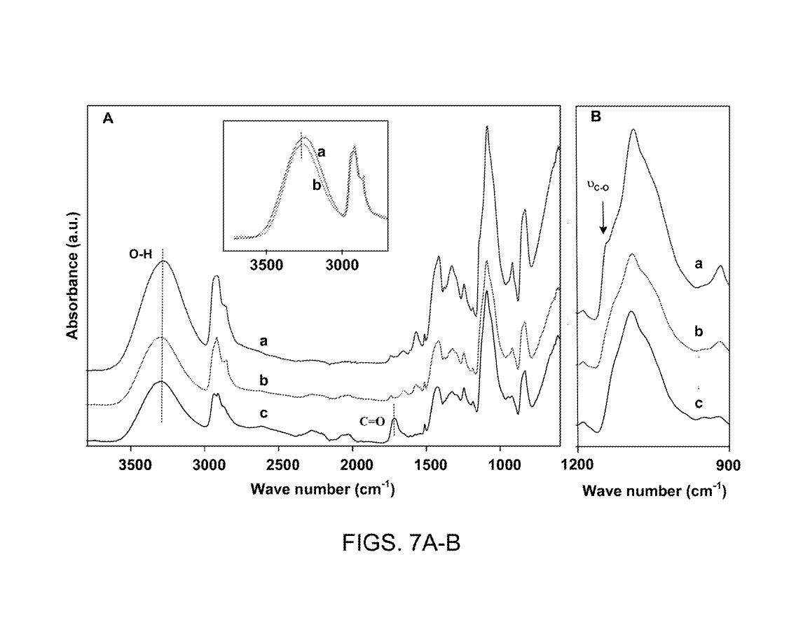

FTIR and XPS were used to examine the incorporation of Polybrene and Poly(MVE/MA) with the PVA polymer. FTIR spectra of PVA, PVA/Polybrene and PVA/Poly(MVE/MA) fibers are presented in FIGS. 7A-B. Addition of Poly(MVE/MA) is clearly confirmed by the absorbance peak at 1730 cm⁻¹ attributed to the C═O group. Polybrene has weaker absorbance in the IR region and was difficult to identify with FTIR. FTIR measurements show absorbance peaks to be slightly different among the samples in the peak intensity for O—H at 3550-3100 cm⁻¹ and in the peak shape between 1200˜900 cm⁻¹. In the inset of FIG. 7A, the spectra of PVA and PVA/Polybrene fibers were normalized using the peak at 1097 cm⁻¹ (C—O stretching vibrations at the non-hydrolyzed group in PVA) (Rocha de Oliveira A A, Gomide V S, Leite MdF, Mansur H S, and Pereira MdM. Materials Research (Sao Carlos, Brazil) 2009; 12 (2):239-244). Changes in intensities and shifts in peaks in this region (O—H) reflect hydrogen bonding between PVA and the additive polymers (Cho D, Woo J B, Joo Y L, Ober C K, and Frey M W. The Journal of Physical Chemistry C 2010; J. Phys. Chem. C2011 115 (13), 5535-5544). The O—H peak decreased slightly in intensity and varied in shape with the addition of functional polymers in the PVA fibers. PVA typically forms small, dense, and closely packed monoclinic crystallites (Jang J and Lee D K. Polymer 2003; 44 (26):8139-8146) and the degree of crystallinity of PVA fibers strongly affects the FTIR C-0 stretching peak at 1141 cm⁻¹. As the PVA polymer chains are aligned and folded to make the crystalline structure, the PVA hydroxyl groups form intramolecular and intermolecular hydrogen bonds between PVA chains (Mansur H S, Orefice R L, and Mansur A A P. Polymer 2004; 45 (21):7193-7202). Incorporation of functional polymers into the PVA fibers resulted in strong association of the PVA hydroxyls so that PVA crystallization was disrupted during electrospinning. As the functional polymers were added, the decrease in 1141 cm⁻¹ is clearly observed in the FTIR spectra and no discernible shoulder at 1141 cm⁻¹ is detected at the hybrid fibers (FIG. 7B).

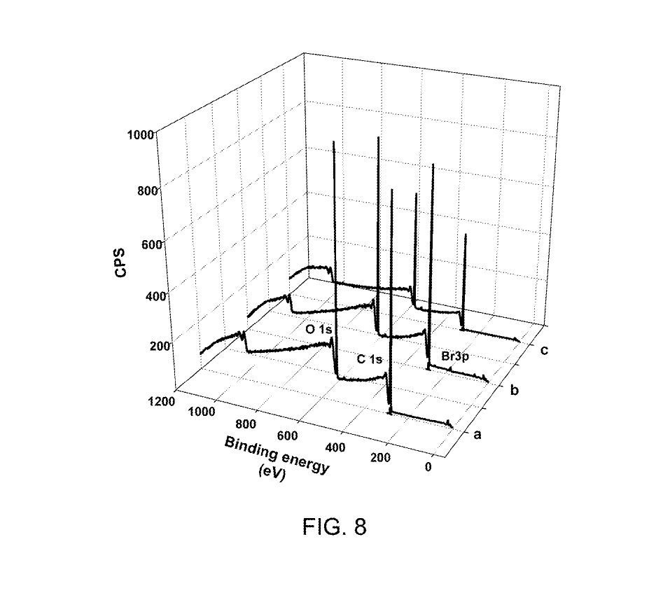

To further investigate the location of the incorporated functional polymers and in particular to have stronger confirmation of Polybrene incorporation, XPS spectra in broad survey mode were recorded to detect and quantify the major atomic elements and bonding patterns at the surface (˜5 nm depth) of the electrospun fiber samples. XPS peaks correspond to specific energy states of electrons in the s or p orbital of their respective atoms. For PVA/Polybrene fibers, the unique Br nucleus associated with Polybrene was used to quantify the proportion of Polybrene at the fiber surface. In PVA/Poly(MVE/MA) fibers, no unique nucleus was available and variations in C to 0 abundance were used to quantify Poly(MVE/MA) relative to PVA. XPS survey spectra (FIG. 8) show the major photoelectron peaks corresponding to the O (1s) and C (1s) at a binding energy of 531 and 285 eV with signal intensities corresponding to the atomic percentage of each element (Li D, Frey M W, Vynias D, and Baeumner A J. Polymer 2007; 48 (21):6340-6347). To evaluate the presence of Br—N associated with Polybrene in the sample surface, the spectra were analyzed in the region of 400 eV and 260 eV˜65 eV where signals of nitrogen and bromine, respectively, appear. Although the Polybrene has two nitrogen atoms and two bromine atoms, XPS spectra contained no measurable signal for nitrogen but measurable peaks for bromine on the surface of the PVA/Polybrene hybrid fibers. The heavy bromine produces a strong XPS signal because it has high relative sensitivity factor (RSF) of 5.03 in XPS compared to nitrogen (RSF 1.8). The bromine peak area can be 5.03/1.8 compared to the nitrogen peak area for equal amount of bromine to nitrogen. The Br (3p) spectrum was not observed in the pure PVA fiber and PVA/Poly(MVE/MA) hybrid fiber but it was present in the PVA/Polybrene hybrid fiber. The amount of bromine in the shell from the fiber surface was determined by comparing the Br/C weight ratio from the results of bromine At % and carbon At % measured by XPS. To calculate the atomic percent (At %) of each element, the weight percent (Wt %) of each element calculated from formulation is divided by its atomic weight and then each result is divided by the total summation of each dividing result.

TABLE 2
Abundance (At %) of elements; measured at the fiber surface by XPS and
calculated from formulation

| | | | PVA/ | | PVA/Poly(MVE/MA) | |
|---|---|---|---|---|---|---|
| | PVA fibers | | Polybrene fibers | | fibers | |
| | XPS | Calculated | XPS | Calculated | XPS | Calculated |
| C | 73.70 | 67.62 | 74.38 | 68.57 | 71.44 | 67.28 |
| O | 26.30 | 32.38 | 25.27 | 30.77 | 28.56 | 32.72 |
| Br | — | — | 0.35 | 0.66 | — | — |

In Table 2, the abundance of elements at the fiber surface is presented, in which the At % of each element is listed from both of the data measured by XPS and the results calculated from each fiber formulation. For these calculations, the full composition of the fibers; PVA/triton X-100: 89/11, PVA/Polybrene/triton X-100: 82/8/10, PVA/Poly(MVE/MA)/triton X-100: 82/8/10, was used including the surfactant. With boiling point>200° C. and vapor pressure<1 mm Hg at 20° C. little of the Triton X-100 is expected to evaporate during the electrospinning process. In all cases, the surface composition of the fibers, as measured by XPS, was richer in carbon, than the overall fiber formulation (calculated). The XPS measurements have confirmed, perhaps not surprisingly, that the carbon rich Triton-X (molecular formula: C₁₄H₂₂O(C₂H₄O)ₙ (n=9-10)) has migrated to the surface of the nanofibers.

Patterned Nanofibers on Chips

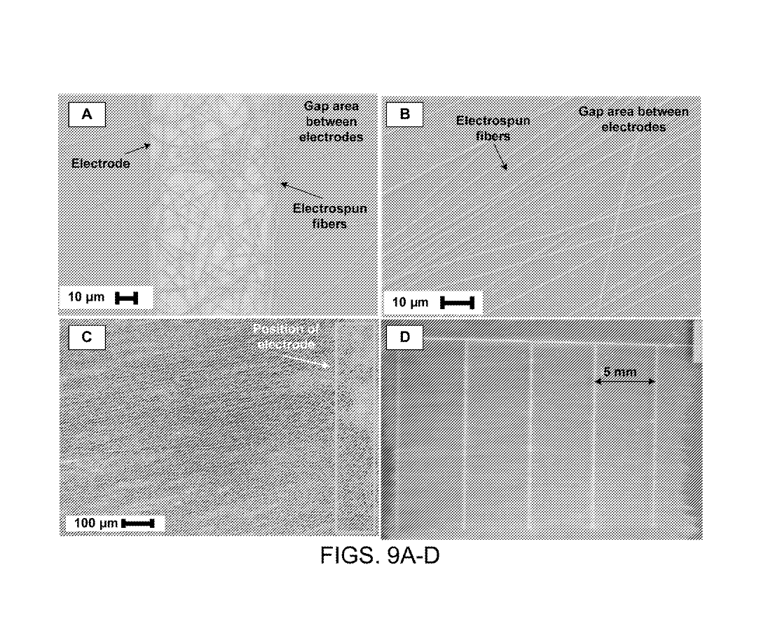

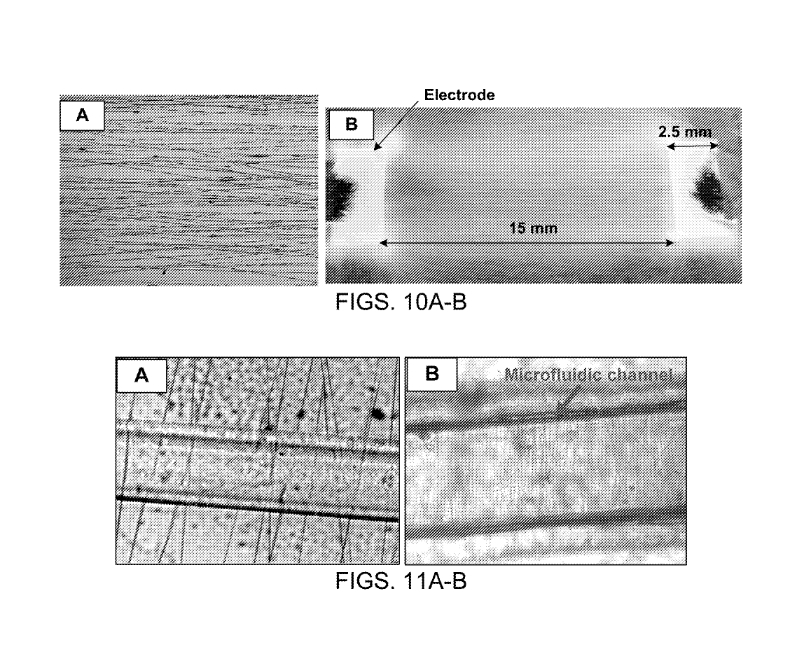

When fibers were collected on chips with grounded gold electrodes, the expected pattern of random fiber orientation on electrodes and extended, aligned fibers between electrodes was observed. As shown in FIGS. 9A-D and 10A-B, the nanofibers were well aligned between electrodes with gap widths ranging from 0.5 mm to 15 mm, or accumulated on the grounded electrodes. At the shortest gap distances (0.5 mm, FIG. 9A), the electrospun nanofibers were stacked on the electrodes and the alignment of nanofibers across the short gap was poor. Increasing the distance between electrodes improved the overall alignment of fibers between electrodes. As the width between the electrodes was increased to 15 mm, the width of the electrode was also found to be important. Fibers electrospun onto chips with thin electrodes (1 mm gold width) spaced 15 mm apart were not well aligned. When the gold electrode width was increased to 2.5 mm, however, the electrospun fibers were well aligned over the 15 mm gap between electrodes (FIG. 10B). This phenomenon was attributed to insufficient effectiveness of the grounding on the 1 mm electrodes. In our experiment, a 5 mm gap between two neighboring electrodes resulted in excellent nanofiber alignment. Therefore, multiple electrodes with 5 mm gaps were fabricated on a PMMA chip for further processing into microfluidic channels (FIG. 9D) with the nanofibers perpendicular to the channel length.

Investigation of Incorporated Nanofibers in a Microfluidic Channel

Assembly of the full microfluidic device incorporating electrospun nanofibers across channels (FIGS. 5A-B) required high pressure, temperature and UV exposure to insure that no leakage would occur when fluids flow through the channels. Images of assembled devices (FIGS. 11A-B) confirm that the electrospun nanofibers maintained alignment and were stable to the chip fabrication process. To determine that these fibers would also be stable during microfluidic device use, nanofibers aligned across the microfluidic channel were tested for their stability during fluid flow through the channels. As a bio-application material, the physical features of the PVA polymer are both strong and weak. The strength is in the hydrophilic property that enhances the interaction of analytes in aqueous solutions. The weakness is the potential dissolution or breakage of the fibers in flowing, aqueous systems, which is likely to destroy the morphology of the electrospun PVA nanofibers. To test the durability of the electrospun nanofibers in the aqueous solutions, solutions were collected from the outlet of the microfluidic device. DI water was flushed through the channels at high flow rates (for microfluidic devices) of 5 μL/min and 20 μL/min (linear velocities of 3.4 and 13.6 mm/s) and the effluent collected. The polymer component elements were analyzed in the effluents using FTIR and H-NMR. A set of standard/calibration specimens were also prepared by dissolving electrospun PVA fibers in DI water at 1.0, 0.1, and 0.01 wt %.

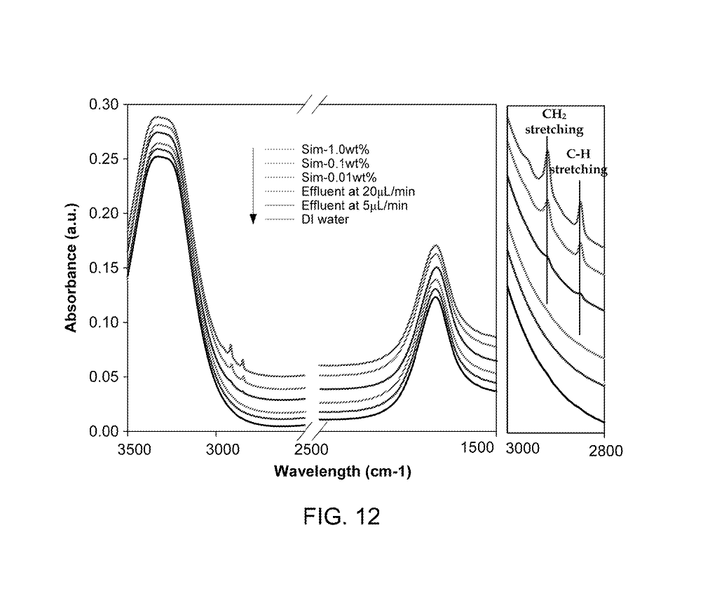

In FTIR analysis (FIG. 12), two characteristic peaks for CH₂ at 2930 cm⁻¹ and CH at 2850 cm⁻¹ were identified. These two peaks originated from PVA nanofibers that had been dissolved and could be identified at PVA concentrations as low as 0.01 wt %. These peaks could not be detected in the effluent collected from the microfluidic channels or in the negative control sample (DI water).

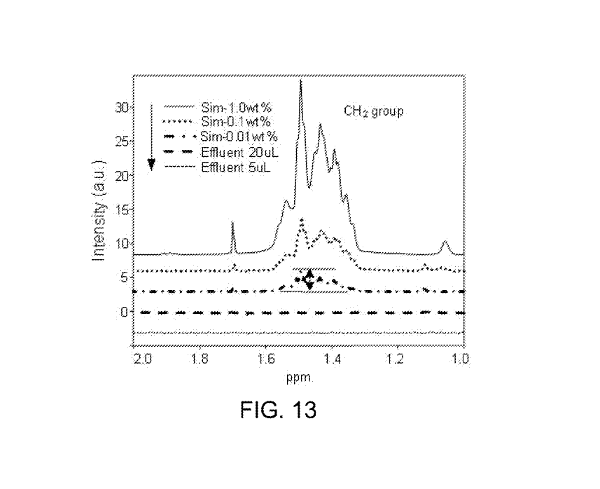

¹H NMR provided additional evidence that fibers were stable within the microfluidic channels and did not dissolve or wash out even at high flow rates. In the ¹H NMR spectra for control samples (FIG. 13) peaks were present at 1.3-4.6 ppm, characteristic of CH₂ in PVA polymer. These peaks were easily identified at all control sample concentrations. As in the FTIR data, nothing was detected in the effluents from the microfluidic devices. The quantity of dissolved PVA polymers in the solutions was estimated so that the presence or absence of these polymers could be assessed. In conclusion, the electrospun PVA nanofibers incorporated in the microfluidic device maintained stability in fiber morphology during fluid flow. The results of FTIR and ¹H NMR demonstrate that PVA electrospun nanofibers are sufficiently stable in the channel to be used in microfluidic devices for bio-analysis.

### 6.1.4. Conclusion

The nanofibers in this example were fabricated to create patterns on the PMMA chip with gold electrodes and integrated into polymer-based microfluidic channels to create functionalized microfluidic systems. Functional polymers with charged chemical groups and a surfactant were successfully incorporated into PVA nanofibers and incorporation of the additives and migration of the surfactant to the fiber surface was confirmed by XPS and FTIR testing. The alignment of nanofibers between two electrodes was achieved by grounding the electrodes and charging the spinneret of the electrospinning device. Fibers were successfully aligned at lengths up to 15 mm. Thus, it is possible to influence the layout of the nanofibers within and across microfluidic channels via electrode placement, size and design. This can be accomplished, for example, by creating nanofiber tufts within microfluidic channels, using them as guiding lines along a channel. A gap between two electrodes of 5 mm was chosen to prepare aligned electrospun nanofibers for further assembly into microfluidic devices with nanofiber aligned perpendicular to the fluid flow direction within microfluidic channels. An evaluation of the hydrophilic nanofibers showed that the nanofibers maintained morphology during flow of DI water at high rates through the microfluidic channel.

### 6.2. Example 2

### Demonstration of Biosensing by Nanofibers in Microfluidic Channels

### 6.2.1. Background

Food- and environmental safety, biosecurity and clinical diagnostics all rely on the ability to detect pathogens, toxins, or clinical markers at low concentrations, accurately and reliably. Simple, over-the-counter biosensors have been developed for some particular cases: the home pregnancy test, and the glucometer for diabetic patients. However, for most detection challenges that we face as a society lengthy and expensive laboratory procedures are required. The costs of the tests and time until results are obtained are insurmountable obstacles. For safety and security-related tests and for diagnostics in resource-limited settings rapid, inexpensive and easy to use tests can have a huge impact.

Over the last three decades, researchers have developed sensing technology that is capable of detecting single cells and even single molecules. However, their detection can only be accomplished either in very clean samples, or by very complicated and costly devices. Microfabrication and nanotechnology have enabled the miniaturization of sensors in the last decade. Yet, most sensors still require a pre-cleaning of the sample prior to its “on-chip” detection.

### 6.2.2. Results

This example demonstrates that nanofibers can be employed as functional components in microchannels. Fibers were spun across the entire volume of the channels in distinct locations. The fibers were made with varying surface chemistries so that different chemical properties could be exploited. The microfluidic channels with functional nanofibers can be used to test a sample for a pathogen or a toxin. Such testing, e.g., for E. coli in apple juice, typically requires three steps: (1) separation of the complex sample into simpler parts, (2) concentration of one of the parts, and then (3) detection of the contaminant. For example, before apple juice can be tested for E. coli, all traces of apple pulp must be removed and bacteria from a large volume collected. Separation and concentration often require bulky, specialized equipment which complicates testing. The nanofibers disclosed herein that are incorporated in microfluidic channels can accomplish all three goals at once, enabling the creation of a “lab-on-a-chip” biosensor.

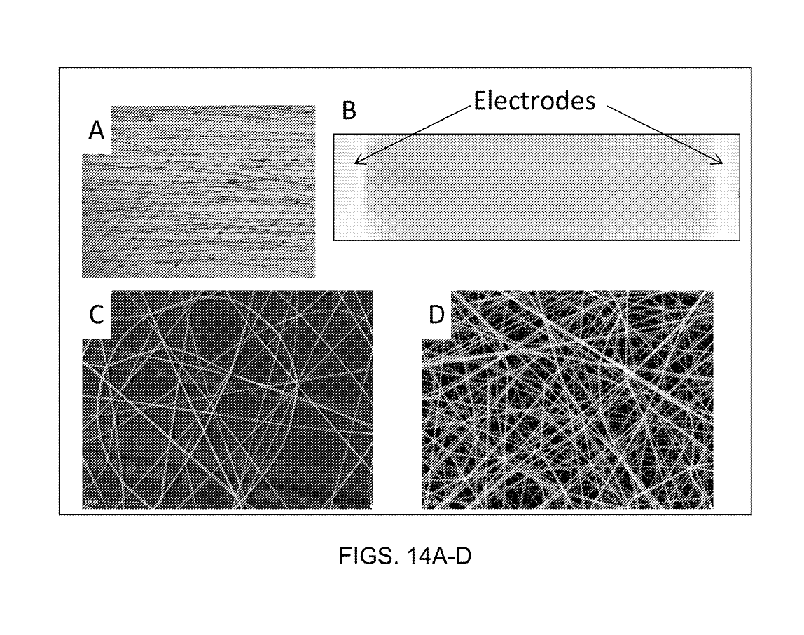

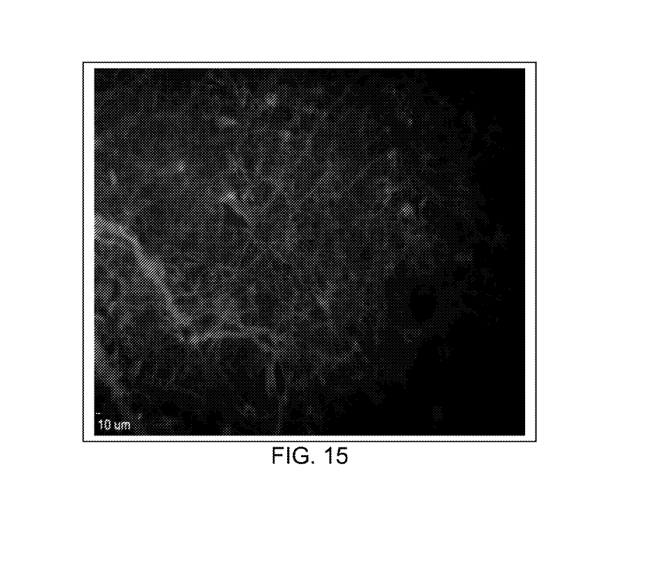

In this example, ball-shaped “test” nanoparticles were captured on the nanofibers disclosed herein and were later be released by a simple pH change (FIGS. 14A-D). E. coli cells were also captured and imaged on the nanofibers (FIG. 15).

As a drop of the suspect material is sent through the microfluidic channel with functional nanofibers, seen in FIGS. 14A-D, the functional nanofibers first clean the sample and then trap the material being tested for. For example, nanofibers embedded with antibodies to E. coli can be used to selectively trap only these disease-causing bacteria, while other bacteria flow through the device. After the disease-causing bacteria are collected and concentrated on the nanofibers, they are easily detected, as shown in FIG. 15.

### 6.3. Example 3

### Nanofibers for Use in Microfluidic Channels in In Vitro Models for Cancer Cell Migration Studies and with Relevant Chemical and Biological Functionality for MicroTAS Systems

This example describes the development of nanofibers from materials compatible with microfluidic in vitro models for cancer cell migration studies and with relevant chemical and biological functionality for microTAS systems. Nanofibers can provide increased surface area and surface functionality patterned at specific locations within channels. Nanofibers have quantifiable and modifiable mechanical, chemical and biological properties that enhance the range of variables addressable in microfluidic devices.

### 6.3.1. Experimental Design

A range of fiber chemical, biological and physical properties has the properties necessary to serve as ECM for specific cell growth within a microfluidic in vitro model, and selectively capture components of a mixed analyte, immobilize proteins or antibodies, and respond to changes in pH within the channels within a microTAS.

Table 1 in Section 5 above summarizes desired properties of the nanofibers and the materials that are used to spin nanofibers delivering each of those properties. A number of methods known in the art can be used to create each type of fiber.

### Methods

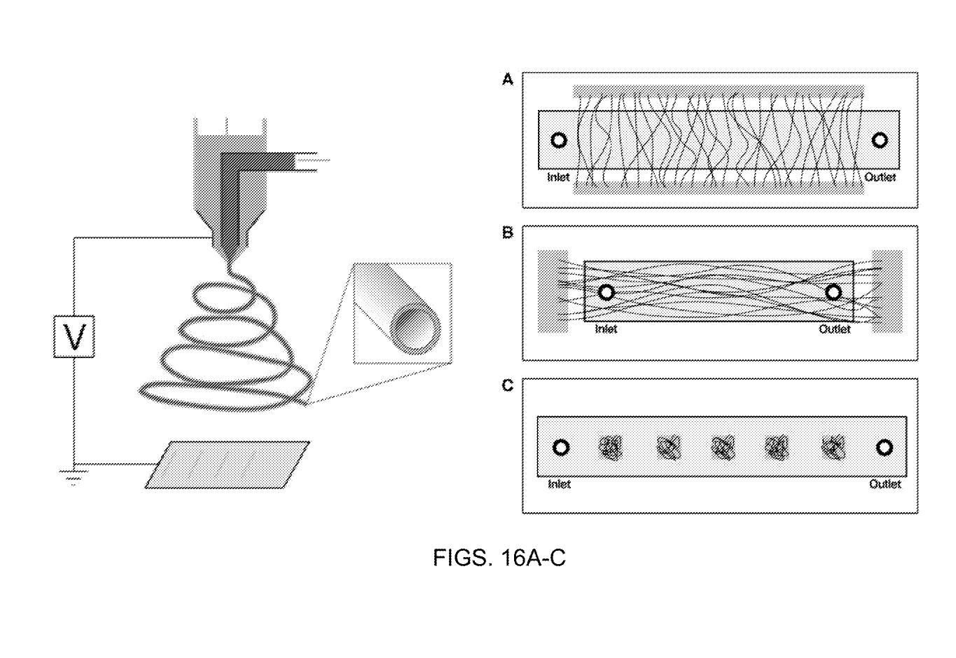

Fibers are produced by electrospinning from solutions of the fiber forming polymer. This process is straight forward, robust and easily tailored to spinning single or multiple fiber types in patterned arrays on microfluidic chips. The electrospinning process is driven by the voltage drop between a droplet of polymer solution and a grounded collector as shown in FIGS. 16A-C. For sterile fiber production, the spinning chamber portion is housed within a sterile, laminar flow hood while other portions of the equipment can be handled outside the sterile area. The grounded collector within the sterile field is the top of a microfluidic device with gold electrodes patterned to guide the fiber collection. By selectively grounding or charging electrodes and physically masking sections of the collector, multiple fibers are patterned on a single chip surface in overlapping or separate regions. For ease of characterization of electrospun fibers by analytical techniques, nanofibers are collected as nonwoven mats and as single fibers on silicon substrates. Non-woven mats are convenient for measurement of hydrophilicity (see, e.g., Xiang, C. H.; Frey, M. W.; Taylor, A. G.; Rebovich, M. E. Journal of Applied Polymer Science 2007, 106, 2363; Xiang, C. H.; Joo, Y. L.; Frey, M. W. Journal of Biobased Materials and Bioenergy 2009, 3, 147), elemental mapping, crystallinity (see, e.g., Xiang, C. H.; Joo, Y. L.; Frey, M. W. Journal of Biobased Materials and Bioenergy 2009, 3, 147) and spectroscopic analysis of the fibers. These techniques are used to confirm presence and activity of chemically and biologically reactive groups within the fibers. The modulus of individual fibers is determined using atomic force microscopy (AFM) measurements of deformation behavior of a single fiber suspended across a trench on a silicon chip (Li, L., et al., Formation and properties of nylon-6 and nylon-6/montmorillonite composite nanofibers. Polymer, 2006. 47 (17): p. 6208-6217).

In microfluidic in vitro systems, nanofibers must mimic ECM in both material and physical properties. Collagen fibers can be electrospun, using methods known in the art, either as 100% type 1 collagen fiber (Li, D., et al., Availability of biotin incorporated in electrospun PLA fibers for streptavidin binding. Polymer, 2007. 48 (21): p. 6340-6347; Li, L. and M. Frey, Preparation and characterization of cellulose nitrate-acetate mixed ester fibers. Polymer, 2010. 51 (16): p. 3774-3783), in blends of collagen and another polymer (Li, L., et al., Formation and properties of nylon-6 and nylon-6/montmorillonite composite nanofibers. Polymer, 2006. 47 (17): p. 6208-6217; Carlisle, C. R., C. Coulais, and M. Guthold, The mechanical stress-strain properties of single electrospun collagen type I nanofibers. Acta Biomaterialia, 2010. 6 (8): p. 2997-3003; Liu, T., et al., Photochemical crosslinked electrospun collagen nanofibers: synthesis, characterization and neural stem cell interactions. Journal Of Biomedical Materials Research. Part A, 2010. 95 (1): p. 276-282; Chen, R., et al., Electrospinning Thermoplastic Polyurethane-Contained Collagen Nanofibers for Tissue-Engineering Applications. Journal of Biomaterials Science—Polymer Edition, 2009. 20 (11): p. 1513-1536.; Chen, Z., et al., Mechanical properties of electrospun collagen-chitosan complex single fibers and membrane. Materials Science & Engineering: C, 2009. 29 (8): p. 2428-2435; Chen, Z. C. C., et al., In vitro and in vivo analysis of co-electrospun scaffolds made of medical grade poly(ε-caprolactone) and porcine collagen. Journal of Biomaterials Science—Polymer Edition, 2008. 19 (5): p. 693-707) or in a sheath/core fiber (Chen, Z. G., et al., Electrospun collagen-chitosan nanofiber: a biomimetic extracellular matrix for endothelial cell and smooth muscle cell. Acta Biomaterialia, 2010. 6 (2): p. 372-382) with a collagen sheath and a polymeric core (Hsu, F.-Y., et al., Electrospun hyaluronate-collagen nanofibrous matrix and the effects of varying the concentration of hyaluronate on the characteristics of foreskin fibroblast cells. Acta Biomaterialia, 2010. 6 (6): p. 2140-2147). 100% type 1 collagen electrospun nanofibers or sheath/core type fibers with a type 1 collagen sheath are prepared. A diagram of the spinning system used for sheath core fiber production is shown in FIGS. 16A-C. In particular, the sheath core type structure are used to create fibers with collagen surface biochemistry and variable stiffness. The core material is made from biocompatible polymers including PLA. By varying the spinning conditions the PLA core can be prepared with high porosity for lower modulus or can be loaded with carbon nanotubes for higher modulus. Variations in modulus can be individually confirmed as described above. The co-axial spinning method can also be used to create fibers with sheaths of other globular proteins (which are poor fiber formers) supported on a core made from an easily spinnable material allowing independent control of surface (sheath) and mechanical (core) properties.

Electrospinning the type 1 collagen protein can present several challenges based on collagen structure, collagen cost and the required purity to support cell growth within microfluidic in vitro devices. To meet these challenges, the electrospinning apparatus can be housed within a laminar flow hood to preserve sterility of fibers produced for this project. To ensure consistent fiber formation and morphology, high purity and well characterized collagen starting material are purchased. Fibers are produced from 100% collagen and also as co-axial fibers with collagen sheath and a biocompatible synthetic polymer core. The coaxial structure provides many advantages and degrees of freedom as described hereinabove (see, e.g., Section 6.2) and the synthetic polymers are significantly less expensive than collagen and can decrease the overall cost of the devices.

### 6.4. Example 4

### Integration of Fibers into Microfluidic Channels

This example describes the integration of fibers into microfluidic channels and assessment of the influence of fiber density, orientation (parallel, perpendicular, random or tufts) on increased collision and reaction rates.

The influence of fiber integration and surface properties on flow, reaction rates and immobilization within microfluidic channels for biofluidic and biosensor applications is characterized. Electrospun nanofiber can be incorporated into microfluidic channels in order to increase surface area, increase collision rates and provide localized surface chemistries within the channels. This enables the isolation, concentration, purification and detection of target analytes from complex sample matrices within just one device in a simple, rapid, and efficient manner.

As demonstrated in Section 6. 1, Example 1, nanofibers can be spun into microfluidic channels made from PMMA. The location of gold electrodes adjacent to the channels was optimized together with electrospinning parameters such as distance of the collector from the syringe tip, polymer concentration and pumping speed. As shown in FIGS. 14A-D, random fiber mats of various density, and lines with appropriate directionality were spun into channels. Using FTIR and NMR measurements the fibers remained within the device even under extreme flow conditions (15 μL/min) and were neither dislocated nor washed out.

### 6.4.1. Experimental Design

Microfluidic channels are created in PMMA for development of microTAS devices. Fibers are spun onto PMMA or glass. Fluids containing known concentrations of positively or negatively charged, or chemically/biologically reactive molecules and particles are pumped through channels containing arrays of nanofibers at varying density. Molecules and particles captured within the channel and those contained in the effluent are analyzed to quantify the nanofiber capture efficiency. Comparing different fiber chemistries spun at similar densities enables the quantification of the fiber chemistry on reaction rates and binding events. Comparing different fiber densities while maintaining the same fiber chemistry leads to a direct comparison of collision rates. Data obtained are used to design optimal systems for bioanalytical detection and cancer cell migration studies.

Methods

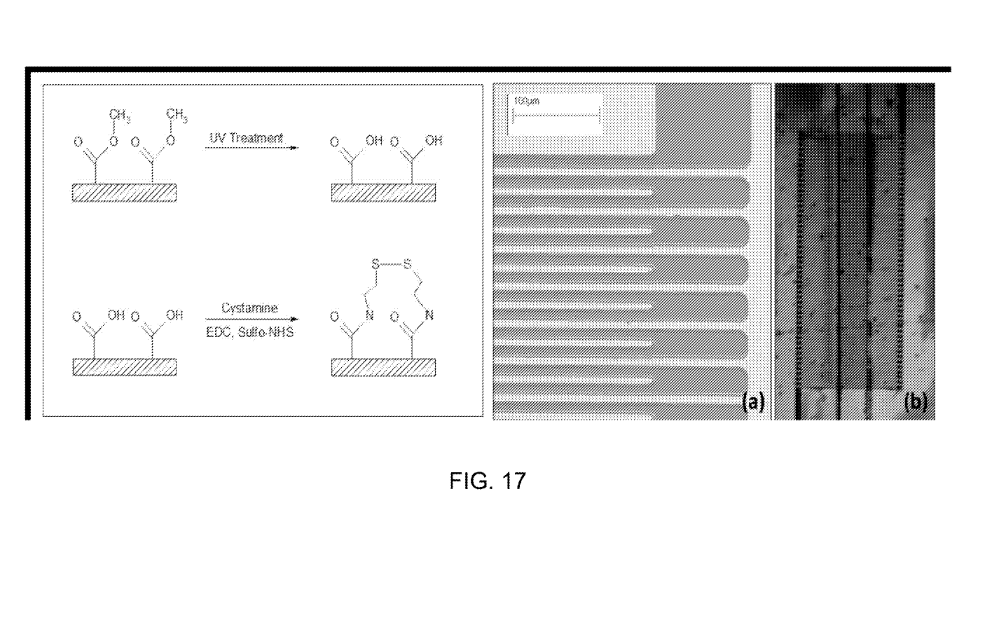

Microfluidic devices in PMMA are made using hot embossing following protocols developed previously (Nugen, S.; Asiello, P.; Baeumner, A. Microsystem Technologies 2009, 15, 477). Briefly, a copper master is fabricated using photolithography and electroplating. Using a hot press, channel structures are then imprinted into the PMMA at 130° C. and 5000 lbs. Channel dimensions generally range from 0.1-1 mm in width and 30-100 μm in depth. Electrodes are fabricated on the cover plate of the device. Protocols developed previously are used (Nugen, S. R.; Asiello, P. J.; Connelly, J. T.; Baeumner, A. J. Biosensors and bioelectronics 2009, 24, 2428). Briefly, gold is evaporated on thiol-primed PMMA for enhanced bonding. Electrode structures are realized via photolithography and metal etching (FIG. 17) (Nugen, S. R.; Asiello, P. J.; Connelly, J. T.; Baeumner, A. J. Biosensors and bioelectronics 2009, 24, 2428). Spacing of 5 mm between the electrodes was previously found to be optimal and can be used for most designs here when straight lines are desirable. For randomly curled nanofiber mats inside the channel, farther spacing of the electrodes can be used.

Nanofibers are spun onto the electrodes (FIGS. 14A-D) as developed previously. Gold electrodes associated with the target nanofiber deposition area are electrically grounded and fibers density is determined by the spinning rate and collection time. This deposition method has been proven to produce reproducible fiber loading within channels and stability of fibers within channels has been confirmed at high flow rates. The flexible electrospinning apparatus allows multiple chip areas and multiple fiber types to be deposited by simply moving the spinneret and ground electrodes and without moving the microfluidic chip.

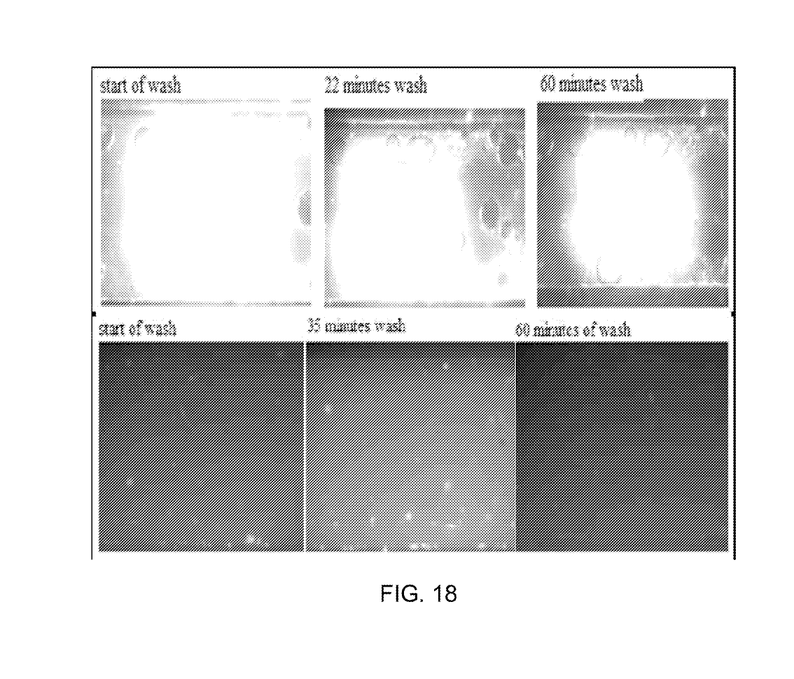

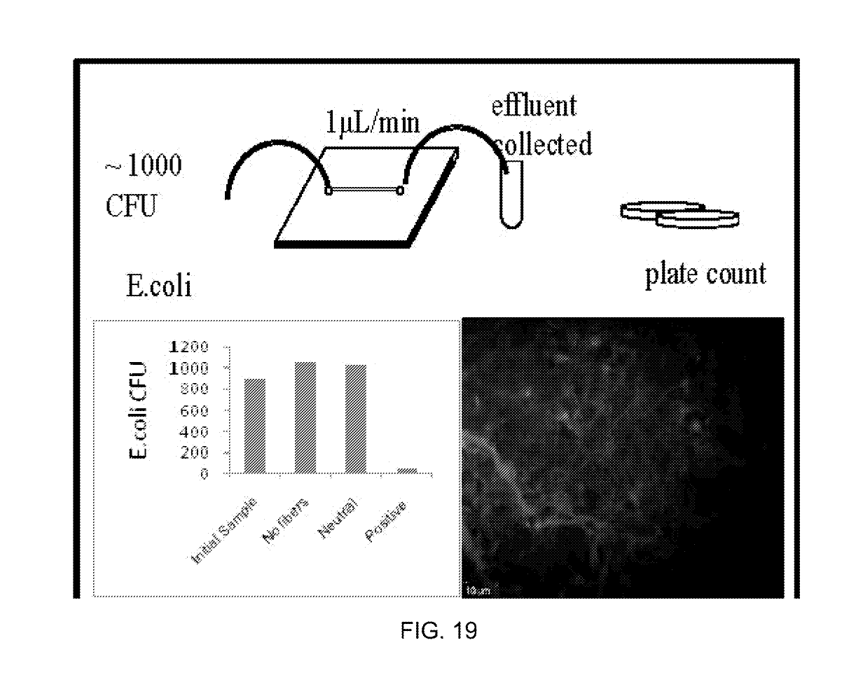

Collision rates and increase in reaction efficiencies are studied using liposome nanovesicles as model system. Sulforhodamine B-entrapping liposomes are quantified using a fluorescence microscope (such as in FIGS. 18 and 19) and image J software. Light microscopy (such as in FIGS. 14A-D) is used for the characterization of nanofiber orientation. Confocal microscopy of fiber mats assists in the characterization of fiber mat density and height. Nanofiber chemistries, density and orientation are studied and optimized based on data obtained.

The use of glass substrates as disclosed in this example may involve slight modification of the gold electrode nanofabrication process. Titanium adhesion layers ensure the adhesion of gold to the glass substrates. Alternatively, chromium or chromium/platinum adhesion layers can be used. In other embodiments, the use of titanium and chromium electrodes without additional gold layers can serve as conducting surfaces during the electrospinning process.

For fiber mats within the channels, a two-layer substrate approach is carried out. The bottom substrate, made of PMMA contains appropriate gold electrode patterns. This is fixed to a top substrate (such as PMMA or glass) onto which the nanofibers are spun. Subsequently, the two polymer substrates are separated and the top layer used for confocal studies prior to microchannel assembly.

### 6.5. Example 5

### Integration of Nanofibers as Pre-Concentration and Immobilization Matrix within Microfluidic Channels

Fiber density and surface chemistry are studied for optimal isolation of model analytes from surface waters, apple juice, urine and fecal matter. Inclusion of biorecognition elements (other than biotin) or parts thereof such as DNA probes, streptavidin, into the polymer spinning dope are investigated for enhanced capture of analytes in the detection zone of the microTAS as time permits.

Nanofibers are spun into distinct locations within a microfluidic channel, providing increased surface area in a random manner and a large number of surface chemistries for interactions with biological molecules. These systems are fabricated and characterized as described hereinabove, and are employed here in sample preparation and detection in microTAS devices. High collision rates yield enhanced interactions of biological molecules with the nanofibers. Analytes are positively isolated out of the sample matrix while interfering substances are negatively isolated or washed out. Thus, highly purified analytes are concentrated and detected in a rapid and simple manner.

Negatively charged nanovesicles (300 nm in diameter) and E. coli cells (negatively charged at pH 7) have been shown to be effectively isolated out of solution using positively charged nanofibers, whereas no vesicles or cells were trapped and isolated out of solution with neutral or negatively charged fibers (FIGS. 18 and 19). Also, nanovesicles and cells remained associated with the fibers upon extensive washing with buffer solutions for extended periods of time (>60 min at 1-5 μL/min flow rates). pH-dependent release of the nanovesicles was easily achieved.

### 6.5.1. Experimental Design

Model analytes are isolated from a variety of matrices. Cholera toxin subunit B is used as a proteinaceous model analyte and Cryptosporidium parvum oocysts are used as a cellular analyte. These analytes can be detected using electrochemical microfluidic biosensors and lateral flow assays with nanovesicle signal enhancement (Abhyankar, V. V., et al., Characterization of a membrane-based gradient generator for use in cell-signaling studies. Lab Chip, 2006. 6 (3): p. 389-93; Shields, J. D., et al., Autologous chemotaxis as a mechanism of tumor cell homing to lymphatics via interstitial flow and autocrine CCR7 signaling. Cancer Cell, 2007. 11 (6): p. 526-38). The model analytes are chosen due to their high importance in drinking water safety, AIDS-related diseases and urgent medical problems in many resource-limited countries. Cholera toxin is detected using anti-cholera toxin antibodies and ganglioside receptors (GM1). C. parvum oocysts are detected using two anti-C. parvum antibodies. In both cases, capture antibodies are immobilized on nanofibers in the detection zone. Nanovesicles, specifically liposomes bearing either the ganglioside receptor or a second antibody subsequently bind to the immobilized target analyte and provide fluorescent signals due to sulforhodamine B entrapped in the inner volume of the liposomes. Matrices that can be employed for both analytes are, e.g., drinking water, environmental surface waters, fecal matter, urine and apple juice.

### 6.5.2. Methods

For the isolation of cholera toxin subunit B from any sample, neutral high density nanofiber mats are used to purify the toxin from larger molecules present in the sample. The cholera toxin subunit B is known to have charge heterogeneity with isoelectric points between 6.5 and 6.8 (Muller, A., et al., Involvement of chemokine receptors in breast cancer metastasis. Nature, 2001. 410 (6824): p. 50-6). Thus proteins are charged negatively at higher pH values and positively at lower pH values. Subsequently, combinations of positively charged nanofiber mats of medium density, and pH variations of the flowing buffer solutions pre-concentrate and further purify the toxin molecules. Upon pH-triggered release, the toxins are concentrated for detection using antibody-coated PLA-biotin nanofibers. Biotinylated antibodies are immobilized via a streptavidin bridge on the PLA-biotin nanofibers in the channel prior to their isolation of cholera toxin subunit B. Detection is accomplished using sulforhodamine-B (SRB) entrapping liposomes bearing 5 mol % GM1 receptor on their outer surface and visualized using a fluorescence microscope.

The purification and toxin isolation process is studied varying nanofiber chemistries, densities and studying possible blocking reagent requirements. Buffer systems used can be based on phosphate buffered saline, HEPES or Tris-based buffers to isolate the toxin out of solution and enable binding of antibodies and receptors. Since the toxins are concentrated within an extremely small area and volume, the limit of detection are very low. Specifically, the detection of cholera toxin subunit B at 1 ng/mL is possible using liposome amplification. In a 1 mm×0.1 mm×0.01 mm segment of channel (width/height/length), the toxins re concentrated within 1 mL, leading to the detection of a total of 1 fg of toxin present in the original sample. Since reasonably wide and high channels are fabricated (1 mm wide, 0.1 mm high), 50-100 μL of sample can be processed within the device at flow rates of 5 μL/min resulting in linear velocities similar to those obtained in smaller electrochemical microfluidic systems with dimensions of up to 0.1 mm width and 0.05 mm height and flow rates of 1-2 μL/min. Based on these numbers, the final limit of detection for the original sample is predicted to be 1 fg/0.1 mL or 10 fg/mL-100× lower than previous ones.

Initial experiments are performed in buffered solution to determine ideal conditions for cholera toxin subunit B isolation, concentration and detection. Subsequently, surface water samples, synthetic urine (while having no relevance to cholera toxin detection, this matrix has relevance to the detection of other protein markers) and supernatant of diluted canine fecal samples is studied next.

Similar experiments can carried out for the detection of C. parvum oocysts from water samples and apple juice. Here, nanofiber mat densities are generally lower than those used for the cholera toxin investigations as oocysts are in the range of 4-5 μm in diameter. EPA approved filtration and pre-concentration protocols (EPA method 1622 [55]) result in the concentration of oocysts via immunomagnetic separation in 0.05 mL final sample volume which can be processed with the microfluidic device.

Positive isolation of model analytes from their sample matrices is then carried out. Biotin-doped PLA nanofibers can also be used for enhanced immobilization of antibodies in the detection zone. DNA probes can also be included in the spinning dope. Here, hsp70 mRNA isolated from C. parvum and amplified via nucleic acid sequence-based amplification (NASBA) are captured via the probes on the nanofiber mats and visualized using DNA-probe tagged liposomes (Abhyankar, V. V., et al., Characterization of a membrane-based gradient generator for use in cell-signaling studies. Lab Chip, 2006. 6 (3): p. 389-93). The availability of DNA probes on the surface of the nanofibers can be investigated using varying concentrations of RNA. This is compared to PLA-biotin nanofibers to which biotinylated DNA probes are immobilized via a streptavidin bridge.

Scaling of assay conditions is also performed. The dimensions of the microfluidic channels are studied with respect to isolation and purification efficiency, volume processed and detection limits obtained.

### 6.6. Example 6

### Functionalized Electrospun Nanofibers as Bioseparators in Microfluidic Systems

This example demonstrates that functionalized electrospun nanofibers can be integrated into microfluidic channels to serve as on-chip bioseparators. Specifically, poly(vinyl alcohol) (PVA) nanofiber mats were shown to successfully serve as bioseparators for negatively charged nanoparticles. Nanofibers were electrospun onto gold microelectrodes, which were incorporated into poly(methyl methacrylate) (PMMA) microfluidic devices using UV-assisted thermal bonding. PVA nanofibers functionalized with Poly(hexadimethrine bromide) (polybrene) were positively charged and successfully filtered negatively charged liposomes out of a buffer solution, while negatively charged nanofibers functionalized with Poly(methyl vinyl ether-alt-maleic anhydride) (POLY(MVE/MA)) were shown to repel the liposomes. The effect of fiber mat thickness was studied using confocal fluorescence microscopy, determining a quite broad optimal range of thicknesses for specific liposome retention, which simplifies fiber mat production with respect to retention reliability. Finally, it was demonstrated that liposomes bound to positively charged nanofibers could be selectively released using a 4-(2-Hydroxyethyl)piperazine-1-ethanesulfonic acid (HEPES)-sucrose-saline (HSS) solution of pH 9, which dramatically changes the nanofiber zeta potential and renders the positively charged nanofibers negatively charged. This demonstrates that functional electrospun nanofibers can be used to enable sample preparation procedures of isolation and concentration in lab-on-a-chip devices. This has far reaching impact on the ability to integrate functional surfaces and materials into microfluidic devices and to significantly expand their ability toward simple lab-on-a-chip devices.

### 6.6.1. Introduction

Micro-total analysis systems (μTAS) incorporate sample preparation and analyte detection into one device that utilizes small feature sizes and volumes in the nano to microliter range. These miniaturized detection assays are portable and permit fast sample analysis and low reagent consumption (S. R. Nugen and A. J. Baeumner, Analytical and Bioanalytical Chemistry, 2008, 391 (2), 451-454; C. A. Batt, Science, 2007, 316, 1579-80; S. Choi, M. Goryll, L. Y. M. Sin, P. K. Wong, J. Chae, Microfluid Nanofluid, 2011, 10, 231-247). These systems can also be designed to allow for parallel processes, permitting multi-analyte detection within one device. However, the decreased sample volumes and smaller feature sizes of these miniaturized devices result in a lower tolerance for particulates and sample impurities. In addition, significant analyte concentration is necessary in order to reduce sample volumes to the nL-μL ranges used by these devices (S. R. Nugen and A. J. Baeumner, Analytical and Bioanalytical Chemistry, 2008, 391 (2), 451-454). While there have been several successful μTAS devices developed, incorporating sample purification and concentration in the same device as analyte detection remains a key challenge for many analysis systems (C. A. Batt, Science, 2007, 316, 1579-80). This research addresses the need for sample preparation within lab-on-a-chip devices through the incorporation of functionalized electrospun nanofibers within polymer microfluidic devices.

Electrospinning is a fiber formation process that uses electrical forces to generate fibers with diameters on the order of 100 nm (D. Li, H. Xia, Advanced Materials, 2004, 16, 1151-1170). The nonwoven mats formed during electro spinning feature extremely large surface area to volume ratios, and can be tailored to have different pore sizes and tensile strengths (D. Li, H. Xia, Advanced Materials, 2004, 16, 1151-1170). Additionally, electrospun nanofibers can be functionalized with a wide range of surface chemistries through the incorporation of true nanoscale materials in the spinning dope (D. Li, M. W. Frey, A. J. Baeumner, Journal of Membrane Science, 2006, 279, 354-363; A. Moradzadegan, S. O. Ranaei-Siadat, A. Ebrahim-Habibi, M. Barshan-Tashnizi, R. Jalili, S. F. Torabi, K. Khajeh, Engineering in Life Sciences, 2010, 10 (1), 57-64; H. Zhou, K. W. Kim, E. P. Giannelis, Y. L. Joo, ACS Symposium Series 918, no. Polymeric Nanofibers, 2006, 217-230). Several interesting fiber chemistries have been developed that would be ideal for use within microfluidic biosensors. Li et al. have successfully electrospun biotinylated nanofibers capable of binding streptavidin in solution (D. Li, M. W. Frey, A. J. Baeumner, Journal of Membrane Science, 2006, 279, 354-363; D. Li, M. W. Frey, D. Vynias, A. J. Baeumner, Polymer, 2007, 48, 6340-6347). In addition, conductive nanofibers have been created using polyaniline, Poly(3,4-ethylenedioxythiophene) poly(styrenesulfonate) (PEDOT:PSS), carbon nanotubes, and other conductive materials (S, Neubert, D. Pliszka, V. Thavasi, E. Wintermantel, S. Ramakrishna, Materials Science and Engineering, 2011, 176 (8), 640-646; S. Shao, S. Zhou, L. Li, J. Li, C. Luo, J. Wang, X. Li, J. Weng, Biomaterials, 2011, 32 (11), 2821-2833; D. Cho, N. Hoepker, and M. W. Frey, Materials Letters, 2012, 68 (0), 293-295). Functionalized nanofibers have previously been incorporated within membranes to allow for immuno and optical sensing (Y. Luo, S, Nartker, H. Miller, D. Hochhalter, M. Wiederoder, S. Wiederoder, E. Setterington, L. T. Drzal, E. C. Alocilja, Biosensors and Bioelectronics, 2010, 26, 1612-1617; X. Wang, C. Drew, S. H. Lee, K. J. Senecal, J. Kumar, L. A. Samuelson, Nano Letters, 2002, 2 (11), 1273-1275; Y. Lee, H. Lee, K. Son, W. Koh, Journal of Materials Chemistry, 2011, 21, 4476-4483). In these applications, nanofibers can be functionalized by adsorbing or covalently bonding antibodies to the fiber surfaces, allowing for detection using colloidal gold, latex beads, or liposomes (Edwards, K. A., Baeumner, A. J. “Liposome-enhanced Lateral-flow Assays for the Sandwich-Hybridization Detection of RNA” in “Biosensors and Biodetection: Methods and Protocols volume 2” Humana Press Books and Journals, Editors Avraham Rasooly, Keith E. Herold, pp. 185-215 (2009)). Finally, graphite and carbon nanofibers have been used to form micro and nanoelectrodes within electrochemical biosensors (T. H. Seah, M. Pumera, Sensors & Actuators B: Chemical, 2011, 156 (1), 79-83; V. Vamvakaki, M. Fouskaki, N. Chaniotakis, Analytical Letters, 2007, 40 (12), 2271-2287).

Several groups have examined the feasibility of incorporating electrospun nanofibers within microfluidic systems. It has been demonstrated that nanofibers maintain their morphology when free floating in low Reynolds number flows (K. Sadlej, E. Wajnryb, M. L. Ekiel-Jezewska, D. Lamparska, T. A. Kowalewski, Int J Heat Fluid Flow, 2010, 31, 996-004.). Nanofibers have also successfully been used as scaffolds for cell growth within microfluidic devices (S. R. Kim, K. H. Lee, K. H. Lee, J. Y. Baek, T. D. Park, K. Sun, S. H. Lee, Proceedings of the 10th International Conference on Miniaturized Systems for Chemistry and Life, 2006, 1387-1390; K. H. Lee, G. H. Kwon, S. J. Shin, J. Y. Baek, D. K. Han, Y. Park, S. H. Lee, Journal of Biomedical Materials Research part A, 2009, 90 (2), 619-628). Recently, we have demonstrated the feasibility of incorporating functionalized PVA nanofibers as filters within microfluidic channels using gold microelectrodes (D. Cho, L. Matlock-Colangelo, C. Xiang, P. Asiello, A. J. Baeumner, M. W. Frey, Polymer, 2011, 15 (7), 3413-3421). Positively and negatively charged nanofibers were created by adding polybrene and Poly(MA) respectively to a PVA spinning dope. These nanofibers were incorporated within PMMA microchannels using Ultra Violet Ozone (UVO)-assisted thermal bonding and were shown to maintain their morphology and functionality in fluid flows up to 20 μL/min for 100 minutes.

In this study, we examine the potential of functionalized electrospun nanofibers to address the need for sample preparation within μTAS devices. The controlled capture and release of negatively charged liposomes containing sulforhodamine B were studied using positively and negatively charged PVA nanofibers within microfluidic channels. The effects of fiber mat thickness, charge, and buffer pH were studied in order to determine the ideal conditions for liposome filtration within microfluidic systems.

### 6.6.2. Materials and Methods

Microelectrode Fabrication

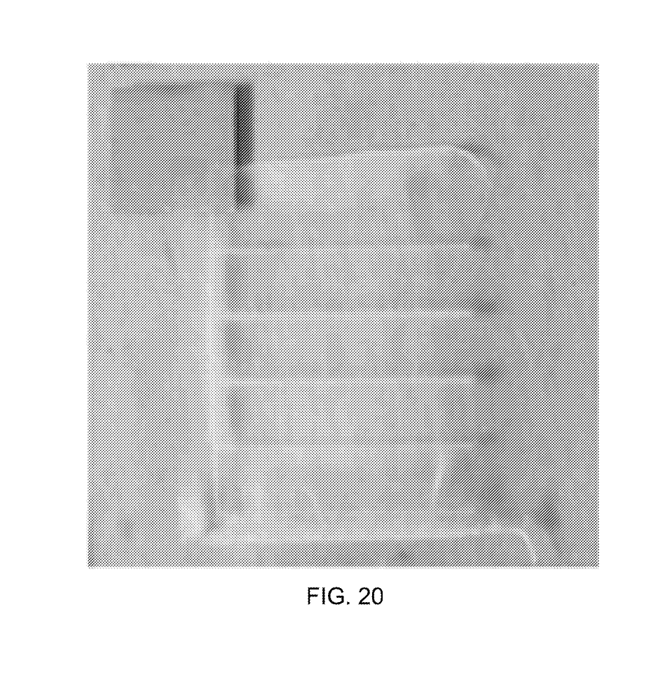

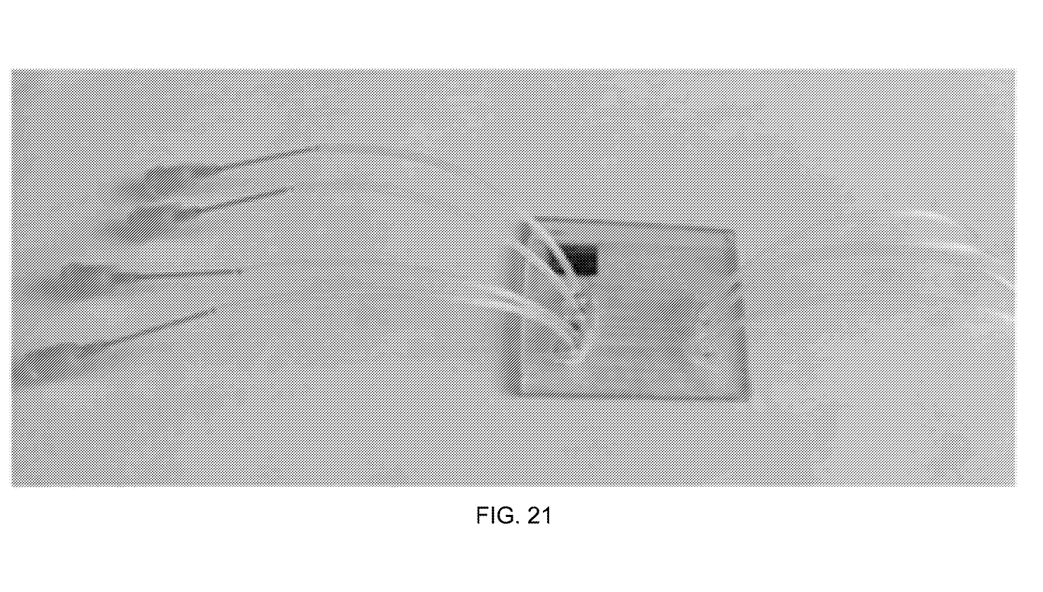

Gold microelectrodes were patterned onto PMMA to serve as grounded collector plates for nanofiber spinning. Electrodes were composed of 1 mm fingers spaced 5 mm apart connected to a large square grounding pad (FIG. 20). The microelectrodes were fabricated at the Cornell NanoScale Science and Technology Facility (CNF) and the Nanobiotechnology Center (NBTC) using a previously described procedure (D. Cho, L. Matlock-Colangelo, C. Xiang, P. Asiello, A. J. Baeumner, M. W. Frey, Polymer, 2011, 15 (7), 3413-3421). Briefly, a CHA Mark 50 evaporator was used to first coat the PMMA pieces with a 10 nm chrome adhesion layer and then a 200 nm gold layer at a deposition rate of 1.5 Å/sec. The gold coated PMMA pieces were coated with Shipley 1813 positive photoresist (Shipley, MA) at 3000 rpm for 30 seconds. The photoresist was then exposed for 11 seconds using an ABM contact aligner and developed in MF 321 for 1 minute (Shipley, MA). The substrates were etched in gold etchant type TFA (Transene, MA) for 1 minute and in chrome etchant for 15 seconds (Cyantek, CA). The remaining photoresist was removed using 100 mM NaOH.

Electrospinning

Nanofibers were spun following a previously described procedure (D. Cho, L. Matlock-Colangelo, C. Xiang, P. Asiello, A. J. Baeumner, M. W. Frey, Polymer, 2011, 15 (7), 3413-3421). Briefly, positively and negatively charged nanofibers were produced by adding polybrene and POLY(MA) (Sigma Aldrich) into a PVA spinning dope (Polysciences Inc., PA). The spinning dope was produced by dissolving 10 wt % PVA into deionized (DI) water in an oven at 95° C. for four hours. To create positively charged nanofibers, polybrene was dissolved in DI water at room temperature and mixed with the PVA solution in a 90/10 wt/wt PVA/polybrene ratio. Triton X-100 was added to the solution and mixed on a vortex for 2 minutes. Negatively charged nanofibers were produced by adding POLY(MA) instead of polybrene to the PVA spinning dope in a 90/10 wt/wt PVA/Poly(MA) ratio. The Poly(MA) was first dissolved in DI water by heating it at 90° C. for 15 minutes. Fluorescent nanofibers of either charge were produced by using the procedure described above and dissolving the PVA in a deionized (DI) water and Cornell Dot solution (CDot; International Patent Application Publication No. WO 2004/063387 A2, Cornell University, Ithaca, NY; see also quantum dots such as Q-Dots, Life Technologies, Grand Island, N.Y.). The solution was prepared with the ratio of 70/30 wt/wt DI water to CDot. CDots are silica spheres with diameters on the nanoscale that are used to encapsulate different dye molecules (H. Ow, D. R. Larson, M. Srivastava, B. A. Baird, W. W. Webb, U. Wiesner, Nano Letters, 2005, 5 (1), 113-117; L. Donaldson, Materials Today, 2011, 14 (4), 131). The CDots contain rhodamine isothiocyanate (TRITC) and produce fluorescent signals when excited at 541 nm (emission at 572 nm).

The spinning solution was loaded into a 5 mL BD plastic syringe with an 18 gauge needle. A positive charge was applied to the syringe needle using a high voltage power supply set at 15 kV (Gamma High Voltage Research Inc., FL). Gold microelectrodes were placed on top of a grounded copper plate and placed 15 cm from the syringe tip. A syringe pump was used to accelerate the spinning solution from the syringe tip at a flow rate of 0.54 mL/h.

Channel Formation and Device Fabrication

Microfluidic channels were embossed into PMMA using a copper template (Nugen S R, Asiello P J, and Baeumner A J. Microsystem Technologies 2009; 15 (3):477-483). Copper templates were fabricated at the CNF using photolithography with KMPR 1050 (Micro-Chem. Corp., MA) and copper electroplating to generate raised copper channels on a copper plate. Channels 52 μm deep and 1 mm wide were embossed into PMMA using a CarverLaminating Hot Press at 130° C. for 5 minutes at 10,000 lbs of pressure. Inlet and outlet holes were drilled at each end of the channel using a 0.8 m steel drill bit. UV-assisted thermal bonding was used to bond the PMMA piece embossed with microchannels and the PMMA piece with the microelectrode and nanofibers. The two PMMA pieces were sandwiched together and pressed on the Carver press for 5 minutes at 90° C. and 8,000 lbs. Polyvinyl chloride tubing with a 0.02″ (0.508 mm) diameter was glued to the inlet and outlet holes (FIG. 21).

Liposome Retention

Microchannels containing either positively or negatively charged nanofibers were filled with liposomes in a HSS buffer (pH 7) solution (1:1000 v/v dilution to a phospholipid concentration of 11.786 μM) at a flow rate of 1 μL/min Liposomes contained 0.44 mol % sulforhodamine B (SRB) conjugated in the lipid bilayer and encapsulated 150 mM SRB to allow for fluorescence imaging (emission 520 nm, excitation 595 nm) (K. A. Edwards, F. Duan, Antje J. Baeumner, John C. March, Analytical Biochemistry, 2008, 380, 59-67). The liposome solution was injected into the channels for 30 minutes and was then washed out using HSS buffer (pH 7) at 1 μL/min for 60 minutes. The concentration of liposomes within the channels was monitored by taking pictures of the channels using a fluorescence microscope. The intensity of fluorescence within the channels was analyzed by using Photoshop to determine the mean red pixel intensity of the images.

Effect of Fiber Mat Thickness

Fluorescent fiber mats with various thicknesses were spun onto gold electrodes by varying the spinning time. The thickness of the fiber mats was measured using the z-scan function of a Leica SP2 confocal microscope. After imaging, the nanofibers were incorporated into microfluidic devices using the thermal bonding procedure described above. Liposomes in a 1:1000 v/v dilution in HSS (final phospholipid concentration of 11.786 μM) were injected into the channels for 30 minutes and then washed with HSS for 60 minutes to determine the effect of fiber mat thickness on liposome retention. Average red pixel intensity within the channels was assessed using Photoshop.

Selective Liposome Release

Microchannels containing positive nanofibers were filled for 30 minutes with a 1:10,000 v/v dilution of liposomes suspended in a HSS buffer at a flow rate of 1 μL/min. The channels were first washed for 30 minutes with HSS buffer (pH 7) to ensure that the liposomes had attached themselves to the nanofibers. The channels were then washed with a HSS solution (pH 9) in order to determine if it is possible to selectively release the liposomes from the positively charged nanofibers.

### 6.6.3. Results and Discussion

Liposome Retention

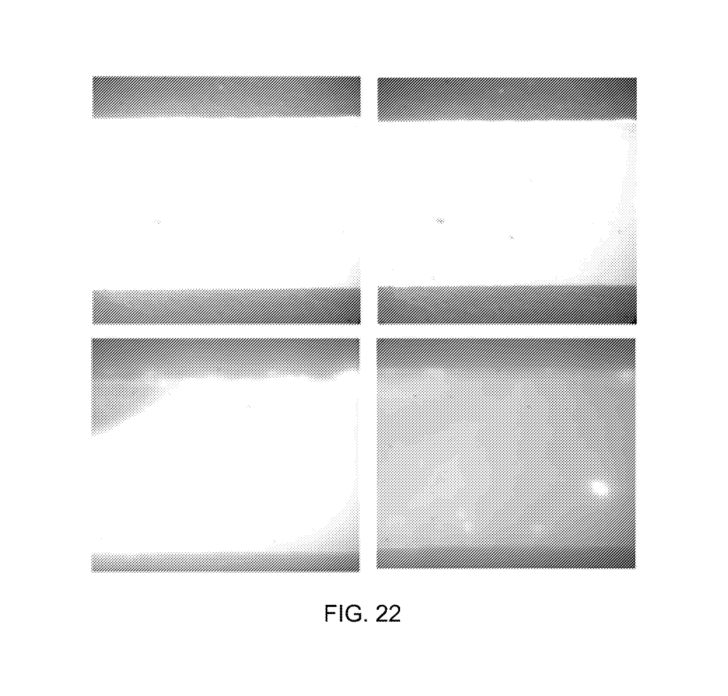

The ability of functionalized nanofiber mats to capture liposomes out of a buffer solution was assessed using microchannels containing either positively or negatively charged nanofibers. Microfluidic channels containing nanofibers were first filled with a liposome solution (liposomes were diluted in HSS) for 30 minutes and then washed with HSS for 60 minutes. The concentration of liposomes within the microchannels was determined by monitoring the fluorescence in the channels during fluid flow. Channels containing nanofiber mats of either charge gained fluorescence during liposome flow, but only channels containing positive nanofibers retained significant fluorescence after the washing step. Moreover, images of the microchannels during fluid flow demonstrated that the liposomes were bound to the surface of the positive nanofiber mats and remained attached even after an hour of fluid flow (FIG. 22).

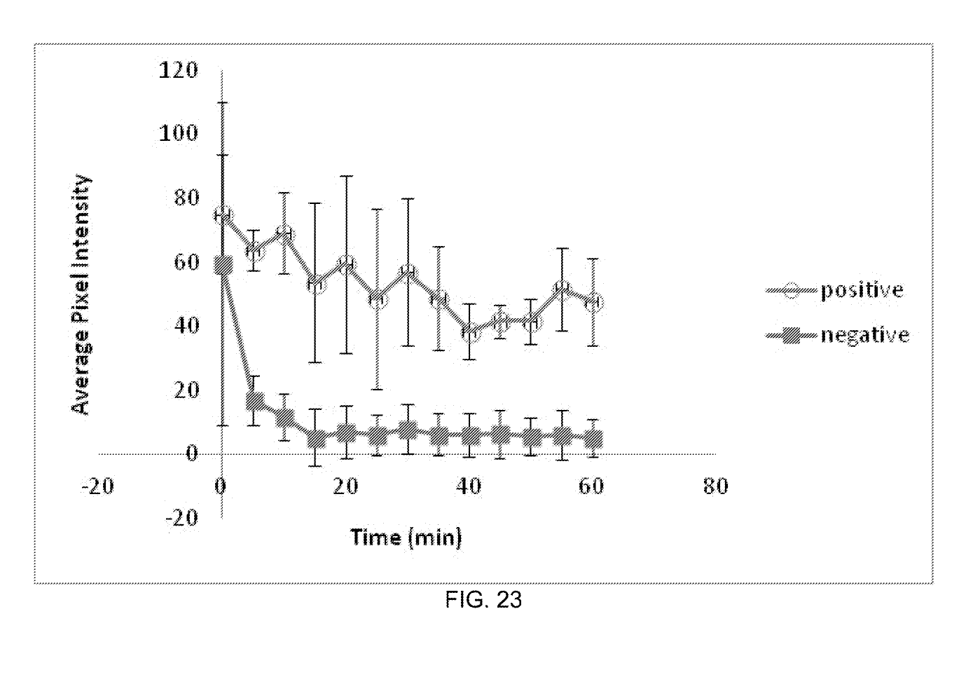

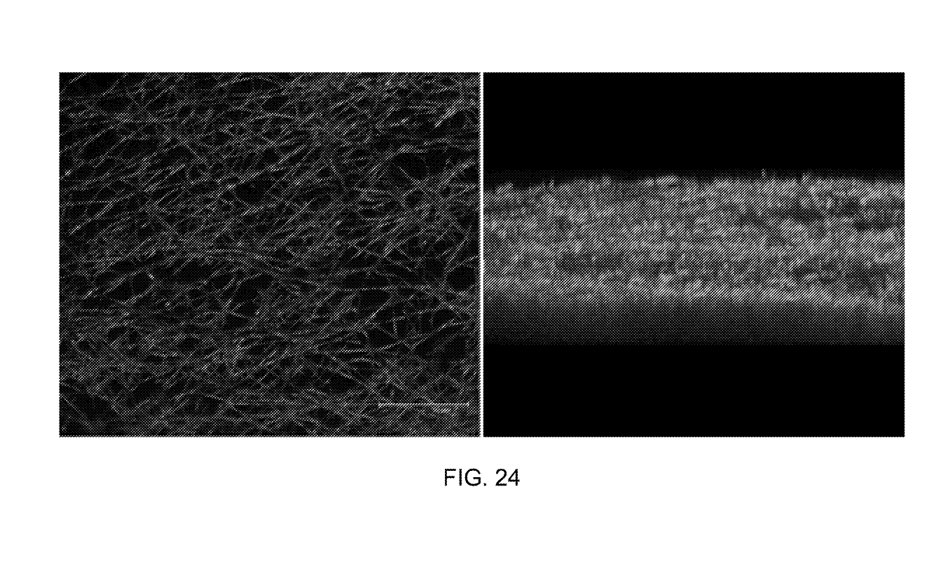

Analysis of fluorescence microscopy images taken during fluid flow confirmed that the microchannels containing positively charged nanofibers retained significantly more fluorescence than the channels containing negative nanofibers (FIG. 23) with average pixel intensities at steady state conditions of at least 40 vs. less than 20 respectively. Some variability in the retention of the different fiber mats after HSS was observed, as indicated by the relatively large standard deviations, which was attributed to variations in the fiber mat thickness and morphology. Consequently, the correlation between nanofiber mat thickness and liposome retention was investigated.

Effect of Fiber Mat Thickness

The effect of fiber mat thickness on liposome retention was determined by electrospinning nanofiber mats of different thickness between 15 μm and 55 μm. We wanted to determine the minimum nanofiber thickness required for liposome isolation while also determining at what thickness retention becomes a function of pore size and not charge interaction. This was accomplished by comparing the retention behaviors of similarly thick positive and negative nanofiber mats. Each nanofiber mat was imaged using a Leica SP2 confocal microscope to determine fiber mat morphology and thickness (FIG. 24).

After confocal measurement, the PMMA chips containing the nanofiber mats were bonded to PMMA chips embossed with microchannels as described above. The completed microfluidic devices were filled with liposomes in HSS buffer for 30 minutes and then washed with HSS buffer for 60 minutes. The liposome retention within the microchannels was analyzed using the average pixel intensity of the channel images during fluid flow. It was determined that negative fiber mats had significant liposome retention at fiber mat thicknesses above 40 μm, indicating that liposomes may be retained because of size exclusion and not charge interaction. Curves similar to those previously shown in FIG. 23 were obtained. Steady state was reached for all nanofiber mats after 5-20 minutes. The average steady state signals for each fiber mat were determined by averaging the pixel intensity for each mat over 45 minutes (Table 3). Positively charged nanofiber mats showed optimal liposome retention at thicknesses of approximately 20 μm and above. The retention of liposomes within the nanofiber mats depends not only on the thickness of the nanofiber mat, but also on its cross-sectional surface area and pore size. Therefore, the nanofiber mat that was 33 μm thick retained more liposomes than the 46 μm nanofiber mat because of its larger cross-sectional surface area and smaller pore size. Some variability in surface area and pore size is to be expected with electrospun nanofibers, however, all the nanofiber mats with thicknesses of 20 μm and above retained a significant number of liposomes.

TABLE 3
Average fluorescent signal observed (and standard deviation
in fluorescent signal) during 45 minutes of HSS wash step in
fiber mats of varying thickness. The standard deviation represents
the variation in pixel intensity of 45 minutes of fluid flow.

| Fiber Charge | Fiber Mat Thickness | Avg. Pixel Intensity | St. Dev |
|---|---|---|---|
| Negative | 19 μm | 0 | 1.0 |
| | 25 μm | 0 | 2.2 |
| | 28 μm | 2.5 | 1.3 |
| | 41 μm | 8.1 | 0.7 |
| | 47 μm | 4.9 | 2.4 |
| Positive | 15 μm | 1.9 | 3.3 |
| | 19 μm | 19.6 | 2.1 |
| | 29 μm | 31.3 | 3.0 |
| | 33 μm | 55.3 | 4.7 |
| | 46 μm | 45.0 | 7.4 |

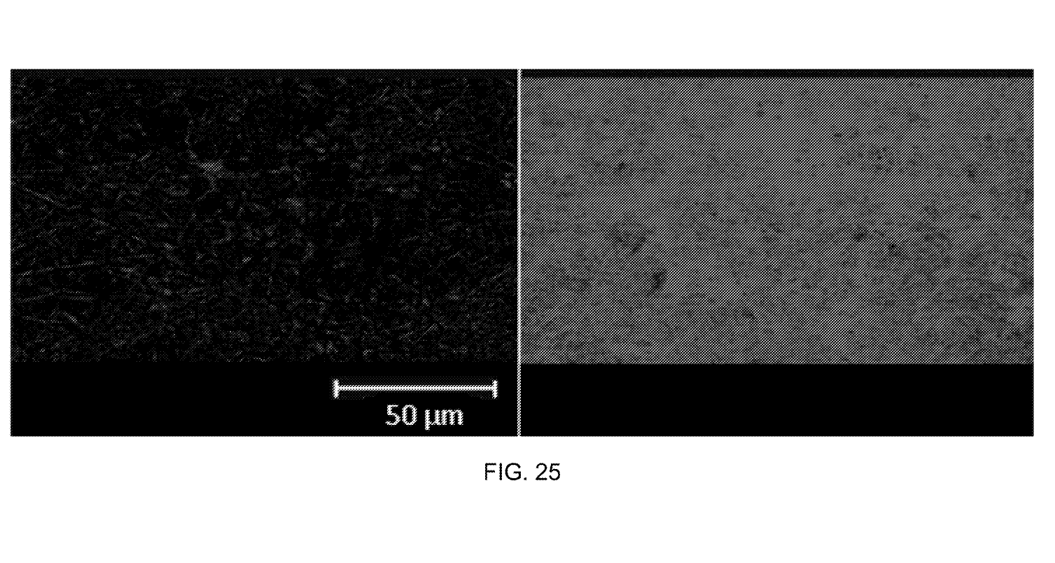

Confocal images were taken of the channels after fluid flow to determine how the fiber mats were affected by bonding and fluid flow. It was determined that the majority of fiber mat thickness is preserved during bonding and liposome flow (Table 4). For nanofiber mats with thicknesses above 39 μm, there was some nontrivial thickness loss observed. At nanofiber mat thicknesses above 39 μm, the pore sizes become smaller, and can result in liposomes being stuck within the mat due to size and not charge. Because of this, the liposomes stuck within the mats may exert a mechanical force on the mat during fluid flow. The resulting increase in force may cause a loss of some nanofibers. However, nanofibers of thickness above 39 um are not used within our devices and therefore there should be no significant nanofiber loss observed. Additionally, comparing the fluorescence of the nanofibers before fluid flow and after liposome flow and wash gave us more insight into the liposome binding behavior of the nanofiber mats. As expected, the fluorescence observed in the positive fiber mats was dramatically higher after liposome flow and HSS wash (FIG. 25).

TABLE 4
A comparison of nanofiber mat thickness before and after fluid
flow for two ranges of nanofiber thickness. Each range represents
the average behavior of four different nanofiber mats.

| Thickness before | Difference in thickness | |
|---|---|---|
| bonding | after fluid flow | St. Dev |
| 18-25 μm | 2 μm | 1.9 μm |
| 39-45 μm | 9.3 μm | 7.9 μm |

Selective Liposome Release

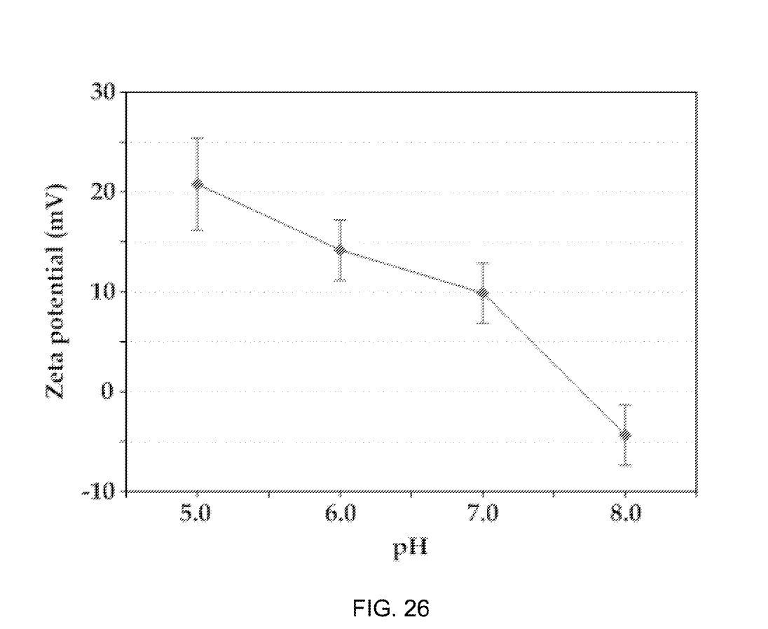

Liposomes contained 0.44 mol % sulforhodamine B (SRB) conjugated within the lipid bilayer and encapsulated 150 mM SRB to facilitate fluorescence imaging. Their zeta potential is negative over a wide pH range (pH 1-11), while polybrene-modified nanofibers have a negative surface charge at pH 8 and above. The nanofiber zeta potential was measured as a function of pH using a microfluidic system (D. Cho, S. Lee, M. W. Frey, J. Colloid Interface Sci., 372, Issue 1, 15 Apr. 2012, Pages 252-260). In FIG. 26, the polybrene incorporated PVA nanofibers show higher positive zeta potential at pH 5, but gradually decreased with the increase of pH. The fibers reveal the zeta potential behavior featuring surface charge whose sign ranges from a positive to a negative value according to the pH levels. Therefore, it should be possible to selectively release liposomes that are bound to polybrene-modified nanofibers using a HSS solution with a pH of 9.

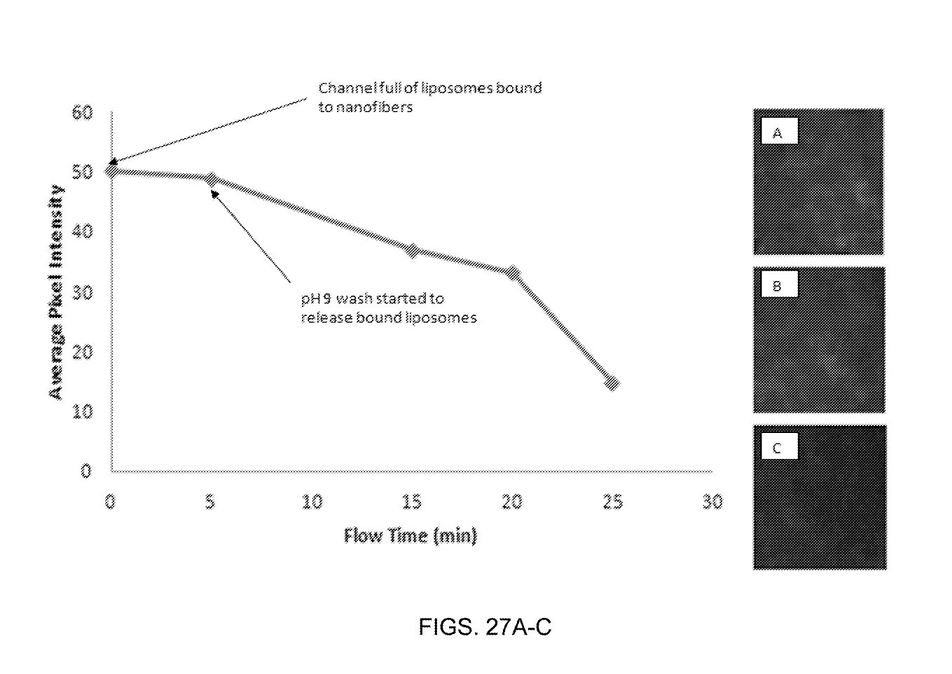

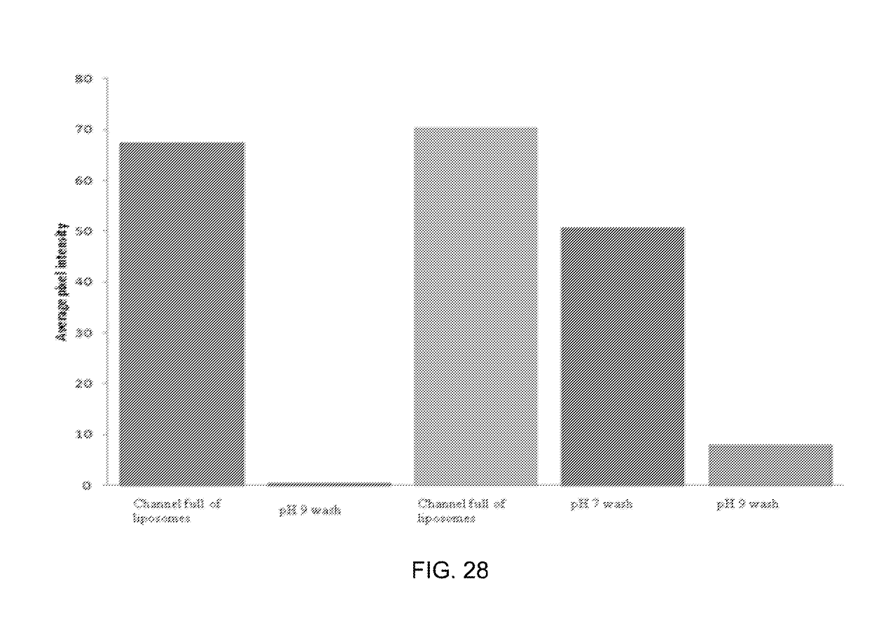

Channels filled with polybrene nanofibers were filled with liposomes in a HSS buffer (pH 7) and were then washed with HSS buffer (pH 7) to demonstrate that the liposomes were successfully bound to the nanofibers (FIGS. 27A-C). The concentration of liposomes within the solution was determined by imaging channels with a fluorescence microscope. As expected, liposomes were successfully bound by the nanofibers. The signals correlated well with those determined earlier with similarly thick nanofiber mats of 25 μm. After 30 minutes, HSS solution (pH 9) was injected into the channels. During the pH 9 wash, the channels demonstrated a nearly 70% decrease in fluorescence, indicating that liposomes were successfully released from the nanofibers as the remaining fluorescence was general background fluorescence in the system (FIGS. 27A-C). Furthermore, microchannels containing positively charged nanofibers were shown to be reusable (FIG. 28). The microchannels were filled with liposomes in a pH 7 HSS buffer for 20 minutes and were immediately washed with a pH 9 HSS solution to demonstrate the successful release of bound liposomes.

After 5 minutes, all the bound liposomes had been released and no fluorescence was observed. The channel was then refilled with liposomes in a HSS solution at pH 7 and a sharp increase in fluorescence, corresponding the binding of liposomes, was observed. A pH 7 wash was performed for 30 minutes to demonstrate that the liposomes were firmly attached to the nanofibers. Finally, the channel was washed with pH 9 HSS solution to remove all the bound liposomes. Once again, the fluorescence within the microchannels disappeared, indicating a successful release of the liposomes.

### 6.6.4. Conclusions

Sample preparation remains a challenge in the design of μTAS devices, as most analytes are contained in complex matrices that require significant purification and concentration to allow for analyte detection. In this example, we have shown that functionalized PVA nanofibers can be used to selectively bind and release desired particulates or analytes within samples. Functionalized PVA nanofibers were incorporated into PMMA microchannels to allow for the capture of negatively charged liposomes out of a buffer solution. Positively charged Polybrene nanofibers were shown to successfully bind liposomes, while negatively charged Poly(MA) nanofibers were shown to repel the liposomes. Further, we determined that nanofiber mats above 20 μm thick demonstrated optimal liposome capture. Finally, we demonstrated that bound liposomes can be selectively released from the nanofiber mats using a HSS solution of pH 9. Thus isolation of diluted analytes from solution within a small nanofiber mat can be accomplished and combined with detection of the bound or released analytes leading to the development of lab-on-a-chip devices with integrated functionalized nanofibers.

The present invention is not to be limited in scope by the specific embodiments described herein. Indeed, various modifications of the invention in addition to those described herein will become apparent to those skilled in the art from the foregoing description. Such modifications are intended to fall within the scope of the appended claims.

All references cited herein are incorporated herein by reference in their entirety and for all purposes to the same extent as if each individual publication, patent or patent application was specifically and individually indicated to be incorporated by reference in its entirety for all purposes.

The citation of any publication is for its disclosure prior to the filing date and should not be construed as an admission that the present invention is not entitled to antedate such publication by virtue of prior invention.

1. A method for producing, in a substrate, an enclosed channel or enclosed cavity comprising at least one functional nanofiber, the method comprising the steps of:
providing a first substrate and a second substrate;
forming a channel or cavity on either the first substrate or the second substrate or on both the first substrate and the second substrate;
depositing at least one conductive surface on a surface of the first substrate or on a surface of the second substrate;
electrospinning at least one functional nanofiber on the first substrate;
assembling the first and second substrates, wherein:
the first substrate is placed over the second substrate, or
the second substrate is placed over the first substrate; and
bonding the first substrate and the second substrate to form the substrate, thereby forming an enclosed channel or enclosed cavity comprising the at least one functional nanofiber in the substrate.

2. The method of claim 1 wherein the first substrate or the second substrate comprises Poly(methyl methacrylate) (PMMA), polycarbonate (PC), polystyrene (PS), Polydimethylsiloxane (PDMS), polyethylene (PE), cyclic olefin copolymer (COC), polymers, agarose, glass, metals or silicon.

3. The method of claim 1 wherein the step of electrospinning the at least one functional nanofiber produces the at least one functional nanofiber in a desired orientation.

4. The method of claim 1 wherein at least one functional nanofiber on the first substrate is positioned partially or in its entirety in a channel or cavity in the first substrate.

5. The method of claim 1 wherein at least one functional nanofiber on the first substrate is positioned partially or in its entirety in functional contact with a channel or cavity in the second substrate upon bonding the two substrates together.

6. (canceled)

7. The method of claim 1 wherein the at least one conductive surface is an electrode.

8. The method of claim 1 wherein the bonding step is irreversible or reversible or wherein the enclosed channel or enclosed cavity is irreversibly or reversibly bonded.

9. The method of claim 1 wherein the nanofiber is conductive.

10. The method of claim 1 wherein the nanofiber comprises a biorecognition element.

11. The method of claim 1 wherein the nanofiber comprises a surface comprising a chemical functionality.

12. The method of claim 1 wherein the nanofiber comprises positive charges and/or negative charges on a surface of the nanofiber.

13. The method of claim 1 wherein the nanofiber comprises a functional group that can be protonated or deprotonated on a surface of the nanofiber.

14. The method of claim 13 wherein the functional group is selected from the group consisting of amine, nitrate, carboxyl, hydroxyl, peroxide, sulfhydryl, maleimide and reactive or protected reactive group.

15. A microfluidic device comprising:
a substrate, wherein the substrate comprises a first substrate and a second substrate bonded together;
at least one conductive surface; and
an enclosed channel or enclosed cavity, wherein the enclosed channel or enclosed cavity comprises:
a portion of the first substrate and a portion of the second substrate bonded together, and
at least one functional electrospun nanofiber positioned in the enclosed channel or enclosed cavity.

16. The device of claim 15 wherein the enclosed channel or enclosed cavity comprises a channel or cavity formed in the first substrate and/or the second substrate prior to the bonding of the first substrate and the second substrate.

17. The device of claim 15 wherein at least one functional nanofiber is positioned within the enclosed channel or enclosed cavity in:
(a) an orientation or direction that is substantially parallel to, or across the width or transverse diameter of the enclosed channel or enclosed cavity or that is substantially parallel to, or along the long (or longest) axis or length of the enclosed channel or enclosed cavity,
(b) a random orientation across the length or across the width of the enclosed channel or enclosed cavity,
(c) a random distribution within the enclosed channel or enclosed cavity, or
(d) a tuft or mat positioned in the interior (or comprised in) the enclosed channel or enclosed cavity.

18. (canceled)

19. The device of claim 15 wherein a step of purifying, isolating, concentrating and/or detecting a sample or analyte of interest is conducted in the enclosed channel or enclosed cavity.

20. An enclosed channel or enclosed cavity, wherein the enclosed channel or enclosed cavity comprises:
a portion of a first substrate and a portion of a second substrate bonded together, and
at least one functional electrospun nanofiber positioned in the enclosed channel or enclosed cavity.
